(19) United States
(12) Patent Application Publication
(10) Pub. No.: US 2026/0293211 A1
(43) Pub. Date: Sep. 24, 2026

(54) Display Device, Electronic Device, And Method Of Manufacturing The Display Device

(71) Applicant: Samsung Display Co., Ltd., Yongin-si (KR)

(72) Inventors: So Young Koo, Yongin-si (KR); Joon Seok Park, Yongin-si (KR); Min Jae Kim, Yongin-si (KR); Hyoung Do Kim, Yongin-si (KR); Ae Ran Song, Yongin-si (KR); Hye Lim Choi, Yongin-si (KR)

(73) Assignee: Samsung Display Co., Ltd., Yongin-si (KR)

(21) Appl. No.: 19/389,675

(22) Filed: Nov. 14, 2025

(30) Foreign Application Priority Data
Mar. 19, 2025 (KR) 10-2025-0035148

(51) Int. Cl. H10D 30/67; H10D 30/01; H10K 59/12; H10K 59/121

(52) U.S. Cl. CPC H10D 30/6755; H10D 30/031; H10K 59/1201; H10K 59/1213

(57) ABSTRACT

A display device includes a substrate and a transistor. The transistor includes an active layer located on the substrate and a gate insulating layer and a gate electrode located on a portion of the active layer. The active layer includes a first pattern located in a central portion of the active layer overlapping the gate electrode in a thickness direction. The active layer also includes a second pattern located in an edge portion of the active layer to surround the first pattern. Further, the first pattern includes a first oxide semiconductor and the second pattern includes a second oxide semiconductor, the second oxide semiconductor having lower mobility than the first oxide semiconductor.

This application claims the benefit of Korean Patent Application No. 10-2025-0035148, filed on Mar. 19, 2025, in the Korean Intellectual Property Office, the disclosure of which is incorporated by reference herein in its entirety.

### TECHNICAL FIELD

Embodiments of the present disclosure relate to a display device, an electronic device, and a method of manufacturing the display device.

### BACKGROUND

As the information-oriented society develops, demand for display devices and electronic devices that can display images in various ways is increasing. Accordingly, various types of display devices and electronic devices, which include pixels for displaying images, are being developed. The display devices may be provided alone or may be included in the electronic devices and used as display screens of the electronic devices. However, the display devices may suffer from a degradation in operating characteristics and reliability.

### BRIEF SUMMARY

Aspects of the present disclosure include a display device and an electronic device, both of which include a transistor with high reliability, and a method of manufacturing the display device.

However, aspects of the present disclosure are not restricted to those set forth above. The above and other aspects of the present disclosure will become more apparent by referencing the detailed description of the present disclosure included below.

According to an aspect of the present disclosure, there is provided a display device including, a substrate, and a transistor including an active layer located on the substrate. A gate insulating layer and a gate electrode are located on a portion of the active layer. The active layer includes a first pattern located in a central portion of the active layer to overlap the gate electrode in a thickness direction of the display device. The first pattern includes a first oxide semiconductor. The active layer also includes a second pattern located in an edge portion of the active layer such that the second pattern surrounds the first pattern. The second pattern includes a second oxide semiconductor having lower mobility than the first oxide semiconductor. The mobility may be a carrier mobility, e.g., electron mobility.

In an embodiment, the second pattern may cover only side surfaces among surfaces of the first pattern and may leave exposed an upper surface of the first pattern, and at least a portion of the upper surface of the first pattern may be covered with the gate insulating layer.

In an embodiment, the first pattern and the second pattern may be arranged so that there is no overlap of the first and second patterns in a thickness direction of the active layer.

In an embodiment, the first pattern and the second pattern may be located at a same height within the transistor. Put another way, both the first pattern and the second pattern may be in a single plane perpendicular to a thickness direction of the transistor.

In an embodiment, the first pattern may have a longer length than the gate electrode and may protrude beyond opposite sides of the gate electrode in a channel length direction of the transistor. Further, the gate insulating layer may cover only a portion of the first pattern which overlaps the gate electrode and may expose the other portion of the first pattern.

In an embodiment, the first pattern may have a shorter length than the gate electrode and may completely overlap the gate electrode in a channel length direction of the transistor. Further, the gate insulating layer may cover an entirety of the first pattern and a portion of the second pattern while leaving exposed other portions of the second pattern.

In an embodiment, each of the first pattern and the second pattern may include a metal oxide including at least one of indium, gallium, zinc, tin, hafnium, zirconium, or aluminum.

In an embodiment, the first pattern may include indium-tin-gallium-zinc oxide or crystalline indium-gallium oxide, and the second pattern may include indium-gallium-zinc oxide.

In an embodiment, the display device may further include a first insulating layer covering the active layer, the gate insulating layer and the gate electrode, and at least one of a source electrode or a drain electrode located on the first insulating layer and electrically connected to the active layer.

In an embodiment, the display device may further include a second insulating layer located on the first insulating layer, and a light emitting element located on the second insulating layer and electrically connected to the source electrode or the drain electrode.

According to an aspect of the present disclosure, there is provided an electronic device including a display module including a display panel which includes a substrate and a transistor, and a processor transmitting an image data signal to the display module. The transistor includes an active layer located on the substrate and a gate insulating layer and a gate electrode are located on a portion of the active layer. The active layer includes a first pattern located in a central portion of the active layer to overlap the gate electrode in a thickness direction of the display device. The first pattern includes a first oxide semiconductor. The active layer also includes a second pattern located in an edge portion of the active layer such that the second pattern surrounds the first pattern. The second pattern includes a second oxide semiconductor having lower mobility than the first oxide semiconductor.

In an embodiment, the second pattern may cover only side surfaces among surfaces of the first pattern and may leave exposed an upper surface of the first pattern, and at least a portion of the upper surface of the first pattern may be covered with the gate insulating layer.

In an embodiment, the first pattern and the second pattern may be arranged so that there is no overlap of the first and second patterns in a thickness direction of the active layer.

In an embodiment, the first pattern may have a longer length than the gate electrode and may protrude beyond opposite sides of the gate electrode in a channel length direction of the transistor. Further, the gate insulating layer may cover only a portion of the first pattern which overlaps the gate electrode and may expose the other portion of the first pattern.

In an embodiment, the first pattern may have a shorter length than the gate electrode and may completely overlap the gate electrode in a channel length direction of the transistor. Further, the gate insulating layer may cover an entirety of the first pattern and a portion of the second pattern while leaving exposed the other portions of the second pattern.

According to an aspect of the present disclosure, there is provided a method of manufacturing a display device. In an embodiment, the method includes: forming an active layer, which includes a first pattern including a first oxide semiconductor and a second pattern including a second oxide semiconductor having lower mobility than the first oxide semiconductor, on a substrate, and forming a gate insulating layer and a gate electrode on a portion of the active layer which includes at least a portion of the first pattern. Upon performance of the method, the first pattern is located in a central portion of the active layer, and the second pattern is located in an edge portion of the active layer to surround the first pattern.

In an embodiment, the forming of the active layer may include: forming the first pattern on the substrate, forming a second semiconductor layer, which includes the second oxide semiconductor and covers the entire first pattern, on the substrate, forming a protective layer on the second semiconductor layer, removing a portion of the second semiconductor layer, which overlaps the first pattern, and removing the protective layer by performing a planarization polishing process until an upper surface of the first pattern is exposed, and forming the second pattern by etching the second semiconductor layer.

In an embodiment, the forming of the active layer may include: forming a first semiconductor layer, which includes the first oxide semiconductor, on the substrate, placing a mask, which covers a portion of the first semiconductor layer, on the substrate and forming the first pattern by etching the first semiconductor layer, forming a second semiconductor layer, which includes the second oxide semiconductor and covers the first pattern and the mask, entirely on the substrate, exposing an upper surface of the first pattern by removing a portion of the second semiconductor layer, which is located on the mask, and removing the mask, and forming the second pattern by etching the second semiconductor layer.

In an embodiment, the method may further include: forming a first insulating layer, which covers the active layer, the gate insulating layer and the gate electrode, on the substrate, and forming at least one of a source electrode or a drain electrode, which is electrically connected to the active layer through a contact hole penetrating the first insulating layer, on the first insulating layer.

In an embodiment, the method may further include: forming a second insulating layer, which covers at least one of the source electrode or the drain electrode, on the first insulating layer, and forming a light emitting element, which is electrically connected to the source electrode or the drain electrode through a via hole penetrating the second insulating layer, on the second insulating layer.

Embodiments provide a display device that includes a transistor, an electronic device that includes a transistor, or methods of manufacturing the display device that includes a method of manufacturing the transistor. The transistor according to the embodiments may include a first pattern including a first oxide semiconductor having high mobility and a second pattern surrounding the first pattern and including a second oxide semiconductor having low mobility. According to embodiments, the operating characteristics and reliability of the transistor and the display device and electronic device, which include the transistor, can be improved.

However, effects according to the embodiments of the present disclosure are not limited to those exemplified above and various other effects are described herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to an embodiment;

FIG. 2 is a plan view of a display panel of FIG. 1;

FIG. 3 is an equivalent circuit diagram of a pixel according to an embodiment;

FIG. 4 is a cross-sectional view of a display panel according to an embodiment;

FIG. 5 is an exploded perspective view illustrating an active layer, a gate insulating layer, and a gate electrode of a transistor according to an embodiment;

FIG. 6 is a plan view illustrating the active layer, the gate insulating layer, and the gate electrode of the transistor according to the embodiment of FIG. 5;

FIG. 7 shows a cross-section of the transistor corresponding to line X1- X1’ of FIG. 6;

FIG. 8 is a graph illustrating the operating characteristics of a transistor including an active layer which includes only a high-mobility oxide semiconductor;

FIG. 9 is a graph illustrating the operating characteristics of a transistor including a first pattern and a second pattern according to an embodiment;

FIG. 10 is a cross-sectional view of a display panel according to an embodiment;

FIG. 11 is an exploded perspective view illustrating an active layer, a gate insulating layer, and a gate electrode of a transistor according to an embodiment;

FIG. 12 is a plan view illustrating the active layer, the gate insulating layer, and the gate electrode of the transistor according to the embodiment of FIG. 11;

FIGS. 13-26 are cross-sectional views illustrating steps in a method of manufacturing a display device according to an embodiment;

FIGS. 27 and 28 are cross-sectional views illustrating steps in a method of manufacturing a display device according to an embodiment;

FIG. 29 is a block diagram of an electronic device according to an embodiment; and

FIG. 30 is a schematic diagram of electronic devices according to various embodiments.

### DETAILED DESCRIPTION

The present disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being "on" another element or layer, it can be directly on the other element or layer, or intervening layers may be present in between the respective elements. Like reference numerals refer to like elements throughout the present disclosure.

It will be understood that, although the terms "first," "second," etc. may be used herein to describe various elements, elements referenced in such manner should not be limited by these terms. These terms are only used to distinguish one element from another element. For instance, a first element discussed below for one embodiment or example could be termed a second element when referenced in another embodiment or example without departing from the teachings of the present disclosure. Similarly, the second element could also be termed the first element.

Features of each embodiment among the various embodiments of the present disclosure may be partially or entirely combined with each other and may interwork with each other in a variety of technical arrangements, and respective embodiments may be implemented independently of each other or may be implemented together in association with each other.

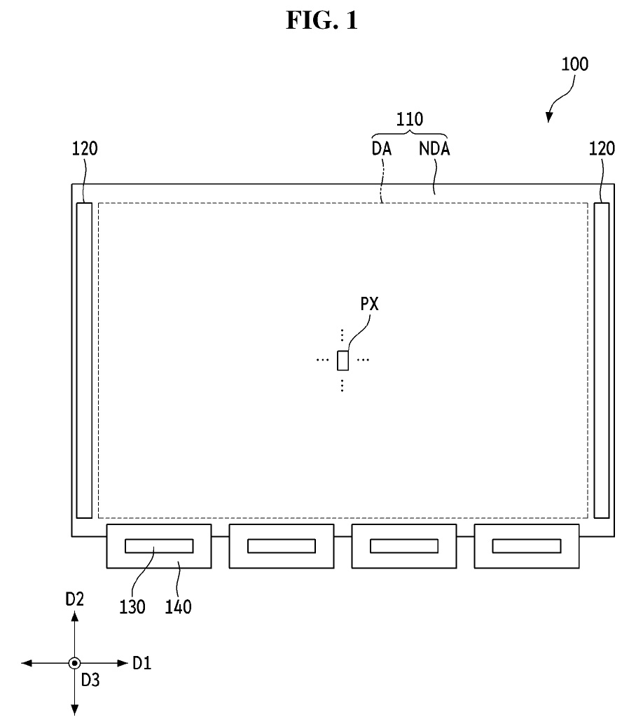

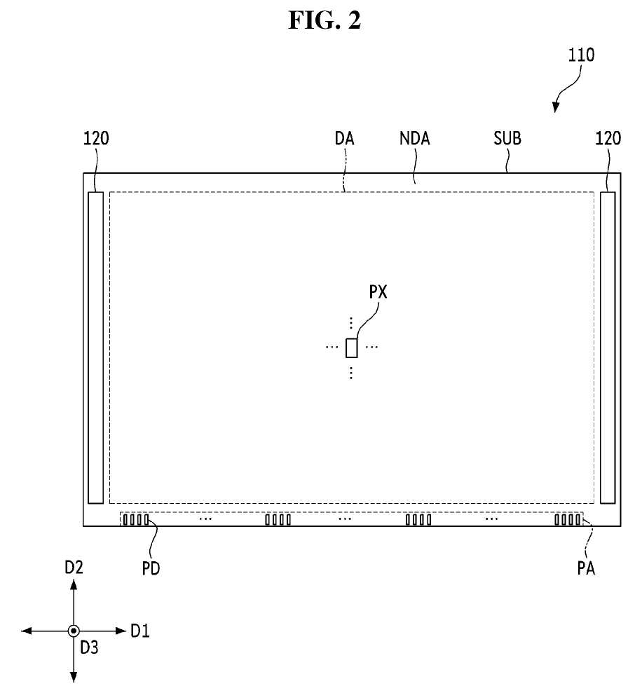

FIG. 1 is a plan view of a display device 100 according to an embodiment. FIG. 2 is a plan view of a display panel 110 of FIG. 1.

Referring to FIGS. 1 and 2, the display device 100 is a device that displays a moving image or a still image. The display device 100 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various electronic devices such as televisions, notebook computers, monitors, billboards and Internet of things (IoT) devices. The display device 100 may also be included in other electronic devices such as a virtual reality (VR) device and an augmented reality (AR) device and may be used to display images in the electronic devices. In an embodiment, an electronic device including the display device 100 may further include a display device housing in which the display device 100 is stored and/or a case or cover for protecting the display device 100.

In an embodiment, the display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode (LED). However, embodiments are not limited to a light emitting display device. For example, the display device 100 may also be a type of display device other than a light emitting display device. Embodiments in which the display device 100 is a light emitting display device (e.g., an organic light emitting display device) are disclosed below.

The display device 100 may include the display panel 110, which includes pixels PX, and a first driver 120 and a second driver 130, which supply driving signals to the pixels PX. The display device 100 may further include additional elements. For example, the display device 100 may further include a power supply unit for supplying driving voltages to the pixels PX, the first driver 120 and the second driver 130 and a timing controller for controlling the operations of the first driver 120 and the second driver 130.

The display panel 110 may include a display area DA and a non-display area NDA. The display area DA is an area where the pixels PX are located and may be an area where an image is displayed by the pixels PX. The non-display area NDA is an area other than the display area DA, and an image may not be displayed in the non-display area NDA. In an embodiment, the non-display area NDA may be located peripherally around the display area DA and may surround the display area DA.

In FIGS. 1 and 2, a first direction D1, a second direction D2, and a third direction D3 are defined. In some embodiments, the first direction D1 may be a horizontal direction of the display panel 110, and the second direction D2 may be a vertical direction of the display panel 110. The third direction DR3 may be a thickness direction of the display panel 110.

In an embodiment, the display panel 110 may have a rectangular shape in plan view. Although FIGS. 1 and 2 illustrate the display panel 110 with a horizontal length longer than a vertical length, the shape of the display panel 110 is not limited to this shape. For example, the display panel 110 may have a shape with a vertical length longer than a horizontal length or may have a square shape. The display panel 110 may include angled corners or rounded corners. The planar shape of the display panel 110 is not limited to the illustrated quadrangular shape and may also be a non-quadrangular polygonal shape, a circular shape, an elliptical shape, an irregular shape, or other shapes.

The display panel 110 may have rigid or flexible characteristics. The display panel 110 may be provided to the display device 100 without being bent or may be provided to the display device 100 while being bent in one or more sections.

The display panel 110 may include a substrate SUB and pixels PX located on the substrate SUB. The pixels PX may be located on the substrate SUB in the display area DA.

The substrate SUB may be a base member of the display panel 110. The substrate SUB may include a display area DA and a non-display area NDA around the display area DA.

The display area DA may have various shapes depending on the embodiment. For example, the display area DA may have a quadrangular shape, a non-quadrangular polygonal shape, a circular shape, an elliptical shape, an irregular shape, or other shapes. In an embodiment, the display area DA may have a shape that matches the shape of the display panel 110.

The pixels PX may be arranged in the display area DA. For example, the display area DA may include pixel areas in which the respective pixels PX are located.

In an embodiment, the display device 100 may be a light emitting display device, and each of the pixels PX may include a light emitting element located in an emission area and a pixel circuit connected to the light emitting element. In the description of embodiments, the term “connection” may be understood as an electrical connection and/or a physical connection. Each pixel circuit may include transistors (e.g., a driving transistor, which generates a driving current corresponding to a data signal, and at least one switching transistor) and at least one capacitor (e.g., a storage capacitor).

The non-display area NDA may include a pad area PA in which pads PD are located. In an embodiment, the non-display area NDA may further include a driving circuit area located on at least one side of the display area DA. At least one driver, the pads PD, and/or wirings may be located in the non-display area NDA.

At least one driver for driving the pixels PX or a part of the driver may be located in the driving circuit area. For example, circuit elements constituting the first driver 120 (e.g., driver transistors and driver capacitors constituting stage circuits of the first driver 120) may be located on the substrate SUB in the driving circuit area. In an embodiment, the circuit elements of the first driver 120 may be formed within the display panel 110 together with the pixels PX.

In an embodiment, the driver transistors included in the first driver 120 may be transistors of substantially the same or similar type and/or structure as the transistors included in the pixels PX and may be formed at the same time as the transistors of the pixels PX. For example, each of the driver transistors may have substantially the same or similar structure and may include the same material as the driving transistor or switching transistor of each of the pixels PX.

The pads PD may be located in the pad area PA. At least one circuit board 140 may be placed and/or bonded on the pad area PA. In an embodiment, a plurality of circuit boards 140 connected to different pads PD may be placed on the pad area PA. The pads PD may include signal pads and power pads for transmitting driving signals and driving voltages, which are needed to drive the pixels PX and/or the first driver 120, into the display panel 110.

The first driver 120 and the second driver 130 may generate driving signals for controlling the operation timing and luminance of the pixels PX and supply the driving signals to the pixels PX. For example, the first driver 120 may be a gate driver including a scan driver and may be connected to the pixels PX through gate lines. The first driver 120 may supply gate signals (e.g., gate signals (including scan signals) for controlling the operation timing of the pixels PX) to the pixels PX. The second driver 130 may be a data driver including source driving circuits and may be connected to the pixels PX through data lines. The second driver 130 may supply data signals to the pixels PX.

In an embodiment, at least one of the first driver 120 and the second driver 130 or a part of at least one driver may be built into the display panel 110. For example, the first driver 120 or a part of the first driver 120 may be placed on the substrate SUB of the display panel 110 and may be placed and/or formed in the non-display area NDA. For example, the first driver 120 may be placed in a part of the non-display area NDA on opposite sides of the display area DA (e.g., left and right sides of the display area DA).

In an embodiment, the other of the first driver 120 and the second driver 130 or a part of the other driver may be placed or formed outside the display panel 110 and electrically connected to the display panel 110. For example, the second driver 130 may be implemented as a plurality of integrated circuit chips and placed on the circuit boards 140 electrically connected to the pixels PX of the display panel 110. Alternatively, the second driver 130 may be implemented as at least one integrated circuit chip and mounted on the non-display area NDA of the display panel 110.

The circuit boards 140 may be connected to the display panel 110 through the pads PD. In an embodiment, each of the circuit boards 140 may be, but is not limited to, a flexible printed circuit board (FPCB), a printed circuit board (PCB), or a flexible film such as a chip on film (COF). In an embodiment, each of the circuit boards 140 may be connected to the timing controller and/or the power supply unit through another circuit board or a connector.

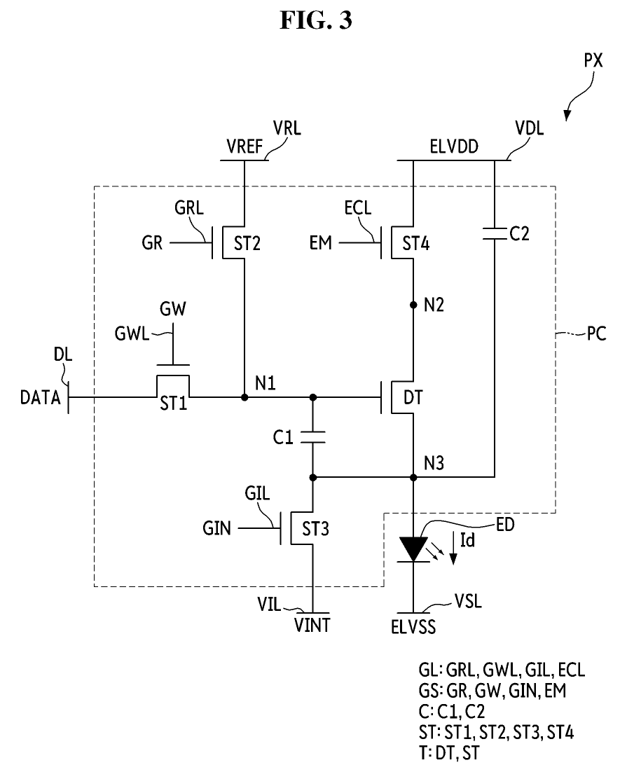

FIG. 3 is an equivalent circuit diagram of a pixel PX according to an embodiment. For example, FIG. 3 shows a pixel PX of a light emitting display device which includes a light emitting element ED. The type and/or structure of the pixel PX that may be included in the display device 100 may vary depending on embodiments.

Referring to FIG. 3, the pixel PX may include a light emitting element ED and a pixel circuit PC electrically connected to the light emitting element ED. The light emitting element ED may be a light source of the pixel PX and may be, but is not limited to, an organic light emitting diode. The pixel circuit PC may control the light emission timing and luminance of the light emitting element ED.

The pixel circuit PC may supply a driving current Id to the light emitting element ED in response to driving signals supplied from the first driver 120 and the second driver 130. For example, the pixel circuit PC may supply the driving current Id to the light emitting element ED in response to gate signals GS supplied from the first driver 120 through gate lines GL, respectively, and a data signal DATA supplied from the second driver 130 through a data line DL.

In an embodiment, the pixel PX may be connected to a first gate line GWL that transmits a first gate signal GW (e.g., a scan signal), a second gate line GIL that transmits a second gate signal GIN, a third gate line GRL that transmits a third gate signal GR, an emission control line ECL that transmits an emission control signal EM, and a data line DL that transmits a data signal DATA. In addition, the pixel PX may be connected to a first power line VDL that transmits a first driving voltage ELVDD (e.g., a high-potential first pixel voltage or anode voltage), a second power line VSL that transmits a second driving voltage ELVSS (e.g., a low-potential second pixel voltage or cathode voltage), an initialization power line VIL that transmits an initialization voltage VINT, and a reference power line VRL that transmits a reference voltage VREF. The types and/or numbers of signal lines and power lines connected to the pixel PX may vary depending on the structure and/or operation method of the pixel PX.

The pixel circuit PC may include transistors T and at least one capacitor C. The transistors T may include a driving transistor DT and at least one switching transistor ST of the pixel PX.

In an embodiment, the pixel circuit PC may include a plurality of switching transistors ST. For example, the pixel circuit PC may include a first switching transistor ST1, a second switching transistor ST2, a third switching transistor ST3, and a fourth switching transistor ST4. In an embodiment, the pixel circuit PC may include a plurality of capacitors C. For example, the pixel circuit PC may include a first capacitor C1 and a second capacitor C2.

The driving transistor DT may control the magnitude of the driving current Id, which is supplied to the light emitting element ED, according to a gate-source voltage. The switching transistors ST may be turned on or off according to their respective gate-source voltages. Depending on the type of each of the transistors T (e.g., a P-type or N-type transistor) and/or operating conditions, a first electrode of each of the transistors T may be a drain electrode (or a drain region) or a source electrode (or a source region), and a second electrode may be an electrode different from the first electrode. For example, when the first electrode is a drain electrode, the second electrode may be a source electrode.

Although FIG. 3 illustrates an embodiment in which all of the transistors T are N-type transistors, the types of the transistors T are not limited to an N type. For example, at least one transistor T may also be formed as a P-type transistor.

In an embodiment, the transistors T may be located in their respective pixel areas and may be oxide transistors (also referred to as “oxide semiconductor transistors”) including oxide semiconductors. For example, an active layer of each of the transistors T may include an oxide semiconductor. However, embodiments are not limited to this example. For example, at least one transistor T may also include a semiconductor material (e.g., amorphous silicon or polysilicon) other than an oxide semiconductor.

In an embodiment, the transistors T located within the display panel 110, including the transistors T included in each pixel PX, may all be oxide transistors that include oxide semiconductors. Oxide semiconductors have high carrier mobility and low leakage current. Accordingly, even if an oxide transistor is driven for a long time, a large voltage drop may be avoided and thus not occur. When the transistors T are formed as oxide transistors, the leakage current of the pixel PX can be reduced or prevented, and the power consumption of the display device 100 can be reduced.

The driving transistor DT may include a gate electrode connected to a first node N1, a first electrode (e.g., a drain electrode or a drain region) connected to a second node N2, and a second electrode (e.g., a source electrode or a source region) connected to a third node N3. The first electrode of the driving transistor DT may be connected to the first power line VDL via the fourth switching transistor ST4, and the second electrode may be connected to the light emitting element ED. The driving transistor DT may control the driving current Id flowing to the light emitting element ED in response to the data signal DATA transmitted to the first node N1.

The first switching transistor ST1 may include a gate electrode connected to the first gate line GWL, a first electrode connected to the data line DL, and a second electrode connected to the first node N1. The first switching transistor ST1 may be turned on by the first gate signal GW (e.g., the first gate signal GW of a gate-on voltage) transmitted to the first gate line GWL to connect the data line DL and the first node N1. Accordingly, the data signal DATA transmitted to the data line DL may be transmitted to the first node N1.

The second switching transistor ST2 may include a gate electrode connected to the third gate line GRL, a first electrode connected to the reference power line VRL, and a second electrode connected to the first node N1. The second switching transistor ST2 may be turned on by the third gate signal GR transmitted to the third gate line GRL to transmit the reference voltage VREF, which is transmitted to the reference power line VRL, to the first node N1.

The third switching transistor ST3 may include a gate electrode connected to the second gate line GIL, a first electrode connected to the third node N3, and a second electrode connected to the initialization power line VIL. The third switching transistor ST3 may be turned on by the second gate signal GIN transmitted to the second gate line GIL to transmit the initialization voltage VINT, which is transmitted to the initialization power line VIL, to the third node N3.

The fourth switching transistor ST4 may include a gate electrode connected to the emission control line ECL, a first electrode connected to the first power line VDL, and a second electrode connected to the second node N2 (or the first electrode of the driving transistor DT). The fourth switching transistor ST4 may be turned on by the emission control signal EM (e.g., the emission control signal EM of a gate-on voltage) transmitted to the emission control line ECL to connect the first power line VDL and the driving transistor DT.

The first capacitor C1 may be connected between the first node N1 and the third node N3. The first capacitor C1 may be a storage capacitor of the pixel PX and may store a voltage corresponding to the data signal DATA (e.g., a data voltage).

The second capacitor C2 may be connected between the first power line VDL and the third node N3. The second capacitor C2 may be a hold capacitor of the pixel PX and may stabilize and/or uniformize the operating characteristics of the pixel PX. In an embodiment, the capacity of the second capacitor C2 may be smaller than the capacity of the first capacitor C1.

The light emitting element ED may be connected between the third node N3 and the second power line VSL. For example, the light emitting element ED may include a first electrode (e.g., an anode) connected to the third node N3, a second electrode (e.g., a cathode) facing the first electrode and connected to the second power line VSL, and a light emitting layer located between the first electrode and the second electrode. In an embodiment, the first electrode of the light emitting element ED may be an individual electrode individually provided in each pixel PX, and the second electrode of the light emitting element ED may be a common electrode shared by a plurality of pixels PX. The light emitting element ED may emit light with a luminance corresponding to the driving current Id during a period in which the driving current Id is supplied from the pixel circuit PC.

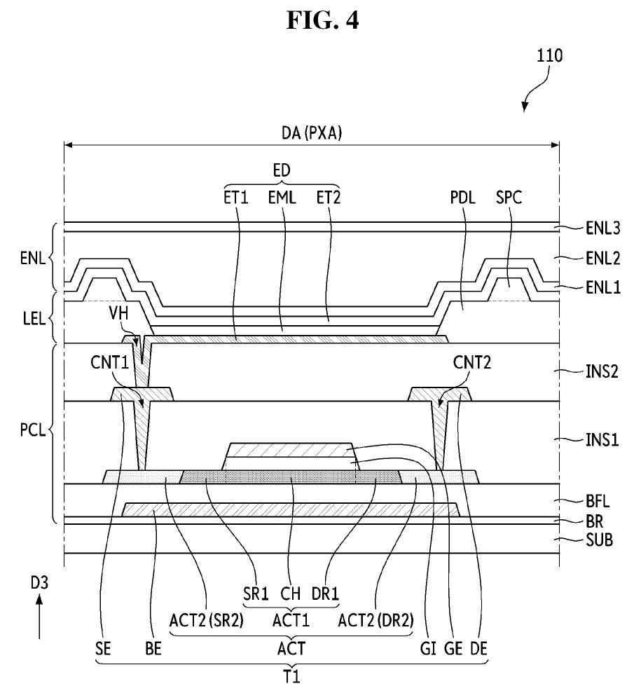

FIG. 4 is a cross-sectional view of a display panel 110 according to an embodiment. For example, FIG. 4 shows a part of the display area DA of the display panel 110. FIG. 4 shows a light emitting display panel including a light emitting element ED (e.g., an organic light emitting diode) as an example of a pixel area PXA of the display panel 110 that may be included in the contemplated embodiments.

Referring to FIG. 4 in addition to the structure shown in FIGS. 1-3, the display panel 110 may include a substrate SUB (or a base layer), a panel circuit layer PCL, a light emitting element layer LEL, and an encapsulation layer ENL. The panel circuit layer PCL, the light emitting element layer LEL, and the encapsulation layer ENL may be located on the substrate SUB to overlap each other in the third direction D3, i.e., the thickness direction. For example, in the display area DA, the panel circuit layer PCL, the light emitting element layer LEL, and the encapsulation layer ENL may be sequentially located on the substrate SUB along the third direction D3. The positions of the panel circuit layer PCL, the light emitting element layer LEL, and/or the encapsulation layer ENL may be different in other embodiments.

In an embodiment, the display panel 110 may further include additional elements provided on and/or under the encapsulation layer ENL. For example, the display panel 110 may further include at least one of a sensor layer (e.g., a touch sensor layer), an optical layer (e.g., a color filter layer and/or a wavelength conversion layer), or a protective layer (e.g., a protective film, an insulating layer, an upper substrate, and/or a window). Each of the sensor layer, the optical layer, and/or the protective layer may be provided on the encapsulation layer ENL or may be provided between the light emitting element layer LEL and the encapsulation layer ENL.

The substrate SUB is a base member for forming the display panel 110 and may be a rigid or flexible substrate (or film). In an embodiment, the substrate SUB may be a substrate that includes an insulating material such as glass and may have rigid characteristics. In this case, the substrate SUB may not be bent. Alternatively, the substrate SUB may be a flexible substrate that includes polyimide or other insulating materials and can be bent, folded, rolled, etc. In this case, the substrate SUB may or may not be bent. The type of substrate, e.g., rigid or flexible and/or material of the substrate SUB may vary depending on the embodiment.

The panel circuit layer PCL (e.g., a pixel circuit layer or a thin-film transistor layer) may be located on the substrate SUB. The panel circuit layer PCL may include circuit elements including transistors T and capacitors C of pixels PX and signal lines and power lines connected to the pixels PX. In an embodiment, the panel circuit layer PCL may further include circuit elements of the first driver 120 (e.g., driver transistors and/or driver capacitors included in the first driver 120) and/or additional conductive patterns (e.g., connection electrodes or connection lines).

FIG. 4 illustrates one transistor T1 located in any one pixel area PXA as an example of the circuit elements that can be included in the panel circuit layer PCL. In an embodiment, the transistor T1 of FIG. 4 may be an oxide transistor including a first oxide semiconductor and a second oxide semiconductor having different mobilities, i.e., different carrier mobilities. For example, at least one transistor T1 included in each pixel PX may be an oxide transistor including a heterogeneous oxide semiconductor. The oxide transistor may be, but is not limited to, an N-type transistor.

Although FIG. 4 illustrates an embodiment in which the transistor T1 (e.g., the driving transistor DT of FIG. 3) that is directly connected to the light emitting element ED of each pixel PX is an oxide transistor including a heterogeneous oxide semiconductor, embodiments are not limited to this example. For example, at least one transistor T1 among the driving transistor DT and the switching transistors ST included in each pixel PX may be an oxide transistor including a heterogeneous oxide semiconductor.

The transistor T1 may include an active layer ACT along with a gate insulating layer GI and a gate electrode GE that overlap the active layer ACT, e.g., in the third direction D3. In an embodiment, the gate insulating layer GI may be located on a portion of the active layer ACT, and the gate electrode GE may be located on the gate insulating layer GI. For example, the gate electrode GE may be located on the gate insulating layer GI which in turn covers a portion of the active layer ACT. The gate insulating layer GI is an element located between the active layer ACT and the gate electrode GE of the transistor T1. In the description of embodiments, the gate insulating layer GI is described as an element included in the transistor T1. However, the gate insulating layer GI may also be considered as a peripheral element located around the transistor T1. For example, the gate insulating layer GI may be an element included in the transistor T1 or the gate insulating layer GI may be a peripheral element located around the transistor T1 that may assist the operation of the transistor T1.

In an embodiment, the transistor T1 may further include at least one of a bottom electrode BE (or a light shielding pattern), a source electrode SE, or a drain electrode DE.

The bottom electrode BE may be located under at least a portion of the active layer ACT including a channel region CH, i.e., further away from the light emitting element ED than the active layer ACT. The bottom electrode BE located under the active layer ACT may block external light from below the active layer ACT from entering the channel region CH, etc. In an embodiment, the bottom electrode BE may be electrically connected to an electrode (e.g., the source electrode SE or the gate electrode GE) of the transistor T1 and may also be utilized as a back-gate electrode (or a bottom-gate electrode) for adjusting the characteristics of the transistor T1.

The source electrode SE may be electrically connected to a source region (e.g., a source region including a first source region SR1 and a second source region SR2) of the active layer ACT. In an embodiment, the source electrode SE may be electrically connected to the second source region SR2 formed in a second pattern ACT2 of the active layer ACT, but embodiments are not limited to this example.

The drain electrode DE may be electrically connected to a drain region (e.g., a drain region including a first drain region DR1 and a second drain region DR2) of the active layer ACT. In an embodiment, the drain electrode DE may be electrically connected to the second drain region DR2 formed in the second pattern ACT2 of the active layer ACT, but embodiments are not limited to this example.

In an embodiment, the transistor T1 may exclude the source electrode SE and/or the drain electrode DE. In this case, the source region SR and/or the drain region DR included in the active layer ACT of the transistor T1 may be directly connected to other circuit elements, wirings, and/or conductive patterns. Alternatively, the source electrode SE and/or the drain electrode DE may be considered as connection electrodes distinct from the transistor T1.

In an embodiment, the panel circuit layer PCL may include a barrier layer BR. For example, the barrier layer BR may be located on the substrate SUB, and circuit elements and wirings may be located on the barrier layer BR.

The barrier layer BR may include a material suitable for protecting the pixels PX from moisture introduced through the substrate SUB which is vulnerable to moisture permeation. For example, the barrier layer BR may include at least one inorganic insulating layer including an inorganic insulating material (e.g., silicon nitride, silicon oxide, silicon oxynitride, titanium oxide, aluminum oxide, or other inorganic insulating materials). The barrier layer BR may be located over the entire display area DA.

The bottom electrode BE may be located on the barrier layer BR. In an embodiment, the bottom electrode BE may be formed under the active layer ACT of at least one transistor T1 (e.g., at least one of the driving transistor DT and the switching transistors ST of FIG. 3) included in each pixel PX.

The bottom electrode BE may overlap the active layer ACT and the gate electrode GE. For example, the bottom electrode BE may be located under the active layer ACT to overlap at least a portion of the active layer ACT including the channel region CH and may face the gate electrode GE with the active layer ACT. The active layer ACT may be located between the bottom electrode BE and the gate electrode GE.

The bottom electrode BE may include at least one conductive material. For example, the bottom electrode BE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) or other metals, an alloy thereof, or other conductive materials. The bottom electrode BE may be formed as a single-layer or multilayer electrode.

A buffer layer BFL may be located on the bottom electrode BE. For example, the buffer layer BFL may be located on the barrier layer BR and the bottom electrode BE. The buffer layer BFL may be located over the entire display area DA and may cover the entire bottom electrode BE. In an embodiment, when the bottom electrode BE is electrically connected to an electrode (e.g., the source electrode SE or the gate electrode GE) of the transistor T1, the buffer layer BFL may be penetrated by a contact hole for connecting the bottom electrode BE and the electrode of the transistor T1.

The buffer layer BFL may be formed as a single-layer or multilayer insulating layer including at least one insulating material. For example, the buffer layer BFL may include at least one inorganic insulating layer including an inorganic insulating material (e.g., silicon nitride, silicon oxide, silicon oxynitride, titanium oxide, aluminum oxide, or other inorganic insulating materials).

The active layer ACT may be located on the buffer layer BFL. In an embodiment, the active layer ACT may have a heterostructure including a first pattern ACT1 and a second pattern ACT2 where the first and second patterns include different oxide semiconductors. For example, the active layer ACT may have a heterojunction structure of the first pattern ACT1 including a first oxide semiconductor and the second pattern ACT2 including a second oxide semiconductor. The first pattern ACT1 may be located in a central portion of the active layer ACT, and the second pattern ACT2 may be located in an edge portion of the active layer ACT separate from and peripheral to the central portion. For example, the second pattern ACT2 may be a frame-shaped semiconductor pattern that surrounds the first pattern ACT1. The first pattern ACT1 and the second pattern ACT2 may be bonded to each other in the horizontal direction, e.g., in the first direction D1, in the second direction D2, or in both.

Each of the first pattern ACT1 and the second pattern ACT2 may include an oxide semiconductor suitable for forming the active layer ACT of the transistor T1. For example, each of the first pattern ACT1 and the second pattern ACT2 may include a metal oxide including at least one of indium (In), gallium (Ga), zinc (Zn), tin (Sn), hafnium (Hf), zirconium (Zr), or aluminum (Al). For example, each of the first pattern ACT1 and the second pattern ACT2 may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO) or indium-tin-gallium-zinc oxide (ITGZO), or other oxide semiconductors.

In embodiments, the first pattern ACT1 and the second pattern ACT2 may include oxide semiconductors having different mobilities, and the first pattern ACT1 may include an oxide semiconductor having a mobility that is high relative to that of the second pattern ACT2. For example, the first pattern ACT1 may include the first oxide semiconductor having high mobility, and the second pattern ACT2 may include the second oxide semiconductor having low mobility, i.e., mobility that is lower than the mobility of the first oxide semiconductor. It should be appreciated that throughout the present disclosure, the term “mobility” is used interchangeably with the term carrier mobility. One example of carrier mobility is electron mobility.

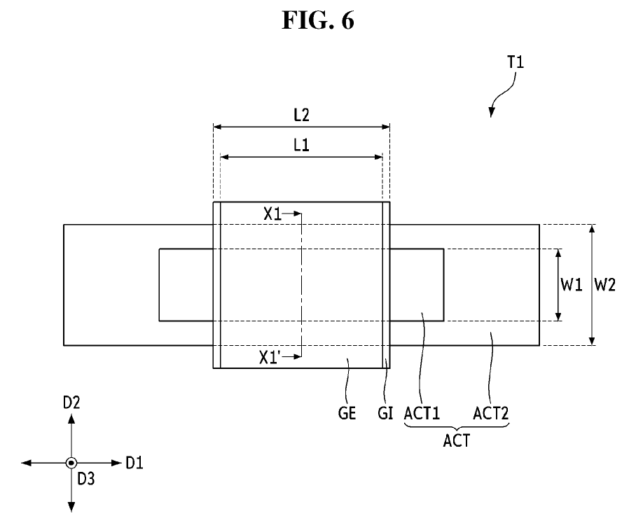

In the description of embodiments, high mobility and low mobility only express a relative difference in mobility between the first oxide semiconductor and the second oxide semiconductor, and the mobility of each of the first oxide semiconductor and the second oxide semiconductor is not limited to a specific value or range. In addition, the mobility of the first oxide semiconductor and the mobility of the second oxide semiconductor may be values measured based on the carrier mobility (e.g., electron mobility) of a portion of the respective first pattern ACT1 and second pattern ACT2 that maintain semiconductor characteristics (e.g., a portion overlapping the gate electrode GE). For example, the mobility of the first oxide semiconductor may correspond to the electron mobility of the first pattern ACT1 in a region (e.g., the channel region CH) where the first pattern ACT1 overlaps the gate electrode GE, and the mobility of the second oxide semiconductor may correspond to the electron mobility of the second pattern ACT2 in a region where the second pattern ACT2 overlaps the gate electrode GE (e.g., a portion in contact with opposite sides of the channel region CH of the first active layer ACT1 in a channel width direction, e.g., the second direction D2 in FIG. 6).

In an embodiment, the first oxide semiconductor of the first pattern ACT1 may be a material having first mobility (e.g., first electron mobility) which is advantageous for securing the operating speed of the transistor T1 and reducing power consumption. For example, the first oxide semiconductor may include indium-tin-gallium-zinc oxide (ITGZO) (e.g., amorphous indium-tin-gallium-zinc oxide (ITGZO)) or indium-gallium oxide (IGO) (e.g., crystalline indium-gallium oxide (p-IGO)) having higher mobility than indium-gallium-zinc oxide (IGZO) (e.g., amorphous indium-gallium-zinc oxide (IGZO)) or may include other high-mobility oxide semiconductors having higher mobility than indium-gallium-zinc oxide (IGZO). For example, the first pattern ACT1 may be an island-shaped semiconductor pattern including amorphous indium-tin-gallium-zinc oxide (ITGZO) or crystalline indium-gallium oxide (p-IGO).

The second oxide semiconductor of the second pattern ACT2 may be a material having second mobility (e.g., second electron mobility) which is advantageous for reducing threshold voltage deviation and leakage current while appropriately securing a driving voltage range of the transistor T1. For example, the second oxide semiconductor may include an oxide semiconductor having mobility that is low relative to that of the first oxide semiconductor, such as indium-gallium-zinc oxide (IGZO) (e.g., amorphous indium-gallium-zinc oxide (IGZO)), or may include other relatively low-mobility oxide semiconductors. For example, the second pattern ACT2 may be a frame-shaped semiconductor pattern that surrounds the first pattern ACT1 and includes amorphous indium-gallium-zinc oxide (IGZO) .

The active layer ACT may include the channel region CH, the source region, and the drain region. In an embodiment, the channel region CH may be formed at least in the first pattern ACT1, and each of the source region and the drain region may be formed in at least one of the first pattern ACT1 or the second pattern ACT2.

The channel region CH may overlap the gate electrode GE in the third direction D3. For example, the channel region CH may be a portion of the active layer ACT located under the gate electrode GE and may be covered by the gate insulating layer GI. A portion of the active layer ACT including the channel region CH may also overlap the bottom electrode BE in the third direction D3.

In an embodiment, the channel region CH may be formed primarily in the first pattern ACT1. For example, the first pattern ACT1 may have relatively higher mobility than the second pattern ACT2. Accordingly, the channel region CH may be formed in the first pattern ACT1. For example, even if the gate electrode GE overlaps a portion of each of the first pattern ACT1 and the second pattern ACT2, a channel may be formed intensively in a portion of the first pattern ACT1 which overlaps the gate electrode GE.

The source region and the drain region may be spaced apart from each other by the channel region CH. The channel region CH may be located between the source region and the drain region. For example, the source region and the drain region may be located on opposite sides of the channel region CH in a channel length direction of the transistor T1, e.g., in the first direction D1 in FIG. 6. The source region may include at least one of the first source region SR1 formed in the first pattern ACT1 or the second source region SR2 formed in the second pattern ACT2. The drain region may include at least one of the first drain region DR1 formed in the first pattern ACT1 or the second drain region DR2 formed in the second pattern ACT2. The source region and the drain region may have higher carrier concentration (e.g., electron concentration) than the channel region CH.

In an embodiment, such as the embodiment depicted in FIG. 6, the first pattern ACT1 may have a longer length than the gate electrode GE in the channel length direction of the transistor T1 and may protrude or extend to opposite sides of the gate electrode GE. When the length of the first pattern ACT1 is longer than a length of the channel region CH of the transistor T1, the proportion or area occupied by the first pattern ACT1 relative to the entire channel region CH of the active layer ACT may increase. Accordingly, the overall mobility of the channel region CH may increase, thereby securing or improving the mobility of the transistor T1.

In addition, when the first pattern ACT1 extends to opposite sides of the channel region CH, the source region SR may include the first source region SR1 formed in the first pattern ACT1 and the second source region SR2 formed in the second pattern ACT2, and the drain region DR may include the first drain region DR1 formed in the first pattern ACT1 and the second drain region DR2 formed in the second pattern ACT2. In this case, and as shown in FIG. 6, for example, the gate insulating layer GI may cover a central portion (e.g., the channel region CH) of the first pattern ACT1 which overlaps the gate electrode GE and may expose peripheral portions (e.g., the first source region SR1 and the first drain region DR1) of the first pattern ACT1.

However, embodiments are not limited to the above case. For example, in a transistor T1 according to an embodiment, the first pattern ACT1 may have a length equal to or smaller than the length of the gate electrode GE in the channel length direction. In this case, the source region SR may include only the second source region SR2 formed in the second pattern ACT2, and the drain region DR may include only the second drain region DR2 formed in the second pattern ACT2.

The gate insulating layer GI may be located on the active layer ACT. In an embodiment, the gate insulating layer GI may be located only in a portion of each pixel area PXA and the display area DA including the pixel areas PXA. For example, the gate insulating layer GI may be located on a portion of the active layer ACT included in each transistor T1.

The gate insulating layer GI may be formed as a single-layer or multilayer insulating layer including at least one insulating material. For example, the gate insulating layer GI may include at least one inorganic insulating layer including an inorganic insulating material (e.g., silicon oxide, silicon nitride, silicon oxynitride, titanium oxide, aluminum oxide, or other inorganic insulating materials).

In an embodiment, the gate insulating layer GI may have a shape and/or size corresponding to a shape and/or size of the gate electrode GE and may be locally located only on a portion of the active layer ACT including the channel region CH. For example, the gate insulating layer GI may only cover a portion of the active layer ACT which includes the channel region CH such that the gate insulating layer GI does not cover other portions of the active layer ACT, the other portions including the source region and the drain region. Since the gate insulating layer GI exposes the source region and the drain region, the source region and the drain region may become conductive more easily during a process of manufacturing the display panel 110. For example, when the gate insulating layer GI is etched to expose the source region and the drain region, a large amount of oxygen vacancies may be generated in the source region and the drain region. Accordingly, the conductivity of the source region and the drain region may be increased in a subsequent process without a separate doping process.

However, embodiments are not limited to the above example. For example, the gate insulating layer GI may be located over the entire display area DA to more completely cover the active layer ACT. In this case, the source region and the drain region of the active layer ACT may be formed to have higher conductivity than the channel region CH by a doping process or may be formed to have higher conductivity than the channel region CH by other methods.

The gate electrode GE may be located on the gate insulating layer GI. The gate electrode GE may be located on the channel region CH of the transistor T1. For example, the channel region CH and the gate electrode GE of the transistor T1 may overlap each other in the third direction D3 and may be insulated by the gate insulating layer GI.

The gate electrode GE may include at least one conductive material. For example, the gate electrode GE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) or other metals, an alloy thereof, or other conductive materials. The gate electrode GE may be formed as a single-layer or multilayer electrode.

A first insulating layer INS1 may be located on the gate electrode GE. For example, the first insulating layer INS1 may be located on the buffer layer BFL, the active layer ACT, the gate insulating layer GI, and the gate electrode GE. The first insulating layer INS1 may be located over the entire display area DA and may entirely cover the active layer ACT, the gate insulating layer GI and the gate electrode GE. In an embodiment, when the transistor T1 further includes the source electrode SE and/or the drain electrode DE, the first insulating layer INS1 may be penetrated by a first contact hole CNT1 for electrically connecting the source electrode SE and the source region SR and/or a second contact hole CNT2 for electrically connecting the drain electrode DE and the drain region DR.

The first insulating layer INS1 may be formed as a single-layer or multilayer insulating layer including at least one insulating material. For example, the first insulating layer INS1 may include at least one inorganic insulating layer including an inorganic insulating material (e.g., silicon oxide, silicon nitride, silicon oxynitride, titanium oxide, aluminum oxide, or other inorganic insulating materials).

The source electrode SE and the drain electrode DE may be located on the first insulating layer INS1. The source electrode SE may be located on the source region of the active layer ACT and may be electrically connected to the source region through the first contact hole CNT1 penetrating the first insulating layer INS1. For example, the source electrode SE may be electrically connected to the second source region SR2 of the second pattern ACT2. If the source region of the active layer ACT is directly connected to another circuit element, connection electrode, and/or wiring, the source electrode SE may be omitted. The drain electrode DE may be located on the drain region of the active layer ACT and may be electrically connected to the drain region through the second contact hole CNT2 penetrating the first insulating layer INS1. For example, the drain electrode DE may be electrically connected to the second drain region DR2 of the second pattern ACT2. If the drain region of the active layer ACT is directly connected to another circuit element, connection electrode, and/or wiring, the drain electrode DE may be omitted.

Each of the source electrode SE and the drain electrode DE may include at least one conductive material. For example, each of the source electrode SE and the drain electrode DE may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) or other metals, an alloy thereof, or other conductive materials. Each of the source electrode SE and the drain electrode DE may be formed as a single-layer or multilayer electrode. When the source electrode SE and the drain electrode DE are formed simultaneously using the same conductive material, they may include the same conductive material and have substantially the same cross-sectional structure.

A second insulating layer INS2 may be located on the first insulating layer INS1, the source electrode SE, and the drain electrode DE. The second insulating layer INS2 may be located over the entire display area DA. In an embodiment, when the transistor T1 is electrically connected to a light emitting element ED on the panel circuit layer PCL, the second insulating layer INS2 may be penetrated by a via hole VH for electrically connecting the transistor T1 and the light emitting element ED. For example, the second insulating layer INS2 may be locally opened in an area where the via hole VH for connecting the source electrode SE of the transistor T1 and a first electrode ET1 of the light emitting element ED is formed.

The second insulating layer INS2 may be formed as a single-layer or multilayer insulating layer including at least one insulating material. For example, the second insulating layer INS2 may include at least one organic insulating layer including an organic insulating material (e.g., acryl resin, epoxy resin, phenolic resin, polyamide resin, polyimide resin, or other organic insulating materials). The second insulating layer INS2 may include an inorganic insulating layer or may not include an inorganic insulating layer. A surface (e.g., an upper surface) of the second insulating layer INS2 may be substantially flat. The second insulating layer INS2 may alleviate or flatten a step caused by the circuit elements (e.g., the transistor T1) and wirings of the panel circuit layer PCL.

The light emitting element layer LEL may be located on the panel circuit layer PCL. For example, the light emitting element layer LEL may be located on the second insulating layer INS2 and may be located at least in the display area DA.

The light emitting element layer LEL may include a light emitting element ED of each pixel PX. For example, the light emitting element layer LEL may include a pixel defining layer PDL (also referred to as a “bank”) that defines an emission area of each pixel PX and a light emitting element ED located in each emission area. In an embodiment, the light emitting element layer LEL may further include a spacer SPC located on a portion of the pixel defining layer PDL.

Each light emitting element ED may include a first electrode ET1 located in an emission area and a light emitting layer EML and a second electrode ET2 sequentially located on the first electrode ET1, as shown in FIG. 4, for example. The first electrode ET1 of the light emitting element ED may be electrically connected to the transistor T1 included in a corresponding pixel PX. For example, the first electrode ET1 of the light emitting element ED may be electrically connected to the source electrode SE of the transistor T1 through the via hole VH penetrating the second insulating layer INS2.

The first electrode ET1 of the light emitting element ED may be a single-layer or multilayer electrode including at least one conductive material. In an embodiment, the display panel 110 may be a top emission display panel, and the first electrode ET1 may include a reflective electrode layer having high reflectivity.

The light emitting layer EML of the light emitting element ED may include a high-molecular material or a low-molecular material and may emit light of a specific color (e.g., a specific wavelength band). For example, the light emitting layer EML may emit red light, green light, blue light, white light, or light of other colors. The light emitting layer EML may include a single light generation layer or may be formed in a tandem structure including a plurality of light generation layers and at least one intermediate layer (e.g., a charge generation layer, etc.). Light emitted from the light emitting layer EML may contribute to image display.

In an embodiment, the light emitting layer EML may be individually formed in the emission area of each pixel PX and may emit light corresponding to the emission wavelength of each pixel PX. For example, the light emitting layer EML included in a red pixel may emit light in a red wavelength band, the light emitting layer EML included in a green pixel may emit light in a green wavelength band, and the light emitting layer EML included in a blue pixel may emit light in a blue wavelength band.

In an embodiment, the light emitting layer EML may be a common layer formed over the entire display area DA and may emit light in a specific wavelength band (e.g., blue light or white light). In this case, a light conversion layer may be located on the light emitting element ED of at least one pixel PX to convert light emitted from the light emitting element ED into light corresponding to the emission wavelength of the corresponding pixel PX.

The second electrode ET2 of the light emitting element ED may include a conductive material. In an embodiment, the second electrode ET2 may be a common layer formed over the entire display area DA to cover the light emitting layer EML and the pixel defining layer PDL. In an embodiment, the display panel 110 may be a top emission display panel, and the second electrode ET2 may include a transparent or translucent electrode layer.

The pixel defining layer PDL may have an opening corresponding to each emission area and may surround each emission area. For example, the pixel defining layer PDL may be formed to cover an edge portion of the first electrode ET1 of the light emitting element ED and may include an opening exposing a central portion of the first electrode ET1. An area where the exposed first electrode ET1 and the light emitting layer EML overlap may be the emission area of each pixel PX. In an embodiment, the pixel defining layer PDL may include at least one organic insulating layer including an organic insulating material.

The spacer SPC may be located on a portion of the pixel defining layer PDL. The spacer SPC may include at least one organic insulating layer including an organic insulating material. The spacer SPC may include the same material as the pixel defining layer PDL or may include a different material from the pixel defining layer PDL. The pixel defining layer PDL and the spacer SPC may be sequentially formed through respective mask processes or may be simultaneously and/or integrally formed using a halftone mask.

The encapsulation layer ENL may be located on the light emitting element layer LEL. The encapsulation layer ENL may cover the light emitting element layer LEL in the display area DA and may extend to the non-display area NDA to contact the panel circuit layer PCL. The encapsulation layer ENL may block the permeation of oxygen or moisture into the light emitting element layer LEL and mitigate electrical and/or physical impact on the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially located on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

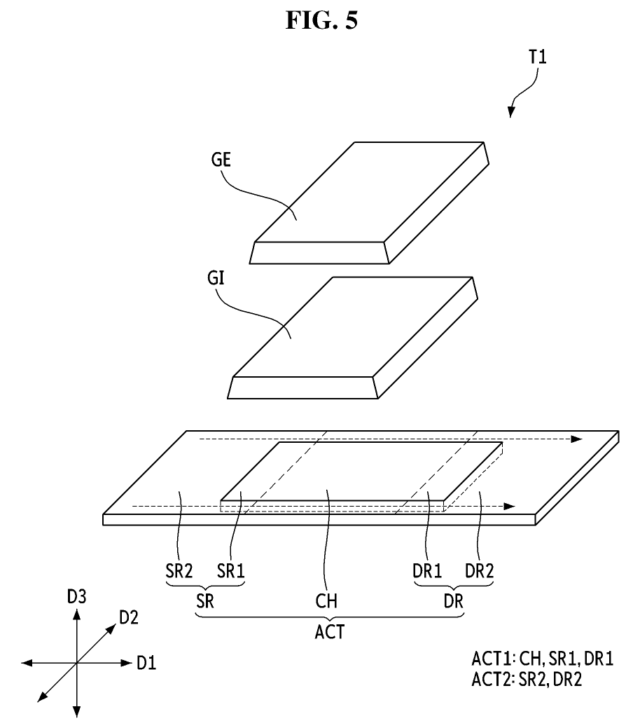

FIG. 5 is an exploded perspective view illustrating an active layer ACT, a gate insulating layer GI, and a gate electrode GE of a transistor T1 according to an embodiment. FIG. 6 is a plan view illustrating the active layer ACT, the gate insulating layer GI, and the gate electrode GE of the transistor T1 according to the embodiment of FIG. 5. In one non-limiting example, FIGS. 5 and 6 show the active layer ACT, the gate insulating layer GI, and the gate electrode GE of the transistor T1 illustrated in FIG. 4.

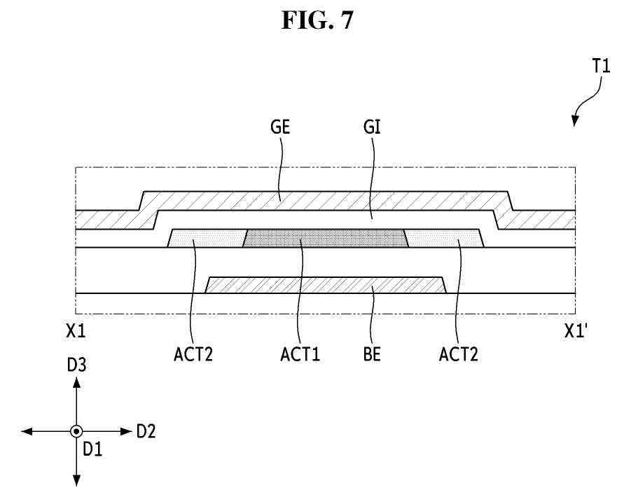

FIG. 7 shows a cross-section of the transistor T1 corresponding to line X1- X1’ of FIG. 6 (the line being a section line).

Referring to FIGS. 5-7 in addition to FIG. 4, the active layer ACT may include a first pattern ACT1 including a first oxide semiconductor and a second pattern ACT2 including a second oxide semiconductor. The first pattern ACT1 may also be referred to as a “first semiconductor pattern” or a “first oxide semiconductor pattern.” The second pattern ACT2 may also be referred to as a “second semiconductor pattern” or a “second oxide semiconductor pattern.”

The first pattern ACT1 may be located in a central portion of the active layer ACT. The first pattern ACT1 may be surrounded by the second pattern ACT2. In an embodiment, the first pattern ACT1 may be formed to have an overall uniform thickness or height.

The first pattern ACT1 may include a channel region CH. The channel region CH may overlap the gate electrode GE in the thickness direction, e.g., third direction D3 and may be covered by the gate insulating layer GI. In an embodiment, the first pattern ACT1 may further include a first source region SR1 and a first drain region DR1 located on opposite sides of the channel region CH in the channel length direction (e.g., the first direction D1) of the transistor T1.

The second pattern ACT2 may be located in an edge portion of the active layer ACT. For example, the first pattern ACT1 and the second pattern ACT2 may lie in the same plane, e.g., plane coincident with first and second directions D1, D2, and the second pattern ACT2 may surround side surfaces of the first pattern ACT1 in such plane. In an embodiment, the second pattern ACT2 may be formed to have an overall uniform thickness or height. In addition, the first pattern ACT1 and the second pattern ACT2 may be formed to have substantially the same or similar thickness or height. For example, the first pattern ACT1 and the second pattern ACT2 may be arranged in the horizontal direction and placed at substantially the same height (or in the same layer) within the transistor T1 and may be bonded to each other in the horizontal direction. In this case, lower surfaces and/or upper surfaces of the first pattern ACT1 and the second pattern ACT2 may be placed side by side at substantially the same height. In addition, the second pattern ACT2 may be located on opposite sides of the first pattern ACT1 in each of the first direction D1 and the second direction D2.

In the thickness direction (e.g., the third direction D3) of the active layer ACT, the first pattern ACT1 and the second pattern ACT2 may not overlap each other. For example, the second pattern ACT2 may cover only the side surfaces among surfaces of the first pattern ACT1 and may not cover the upper surface of the first pattern ACT1. In this case, when viewed in a plane defined by the first direction D1 and the second direction D2, the second pattern ACT2 may include an opening with a size that corresponds to dimensions of the first pattern ACT1 in that plane so that the upper surface of the first pattern ACT1 is exposed. Further, the second pattern ACT2 may be located around the first pattern ACT1 to surround four sides of the first pattern ACT1. At least a portion of the upper surface of the first pattern ACT1 may be covered by the gate insulating layer GI.

A portion of the second pattern ACT2 may overlap the gate electrode GE in the thickness direction and may be covered by the gate insulating layer GI. For example, in the channel width direction of the transistor T1 (e.g., the second direction D2), the second pattern ACT2 may have a width W2 greater than a width W1 of the first pattern ACT1 and may be located on opposite sides of the first pattern ACT1. In addition, a portion of the second pattern ACT2 which overlaps the gate electrode GE may be located on opposite sides of the channel region CH of the first pattern ACT1 in the channel width direction of the transistor T1. Accordingly, the first pattern ACT1 may not be exposed at sides of the active layer ACT in the width direction, e.g., second direction D2. The portion of the second pattern ACT2 which overlaps the gate electrode GE may be a portion having lower mobility than the channel region CH of the first pattern ACT1, and a channel may or may not be formed when the transistor T1 is turned on.

The second pattern ACT2 may further include a second source region SR2 and a second drain region DR2 located on different sides of the first pattern ACT1 in the channel length direction of the transistor T1 (e.g., the first direction D1). In an embodiment, when the first pattern ACT1 includes the first source region SR1 and the first drain region DR1, the second source region SR2 may surround side surfaces of the first source region SR1, and the second drain region DR2 may surround side surfaces of the first drain region DR1.

In an embodiment, the gate insulating layer GI and the gate electrode GE may have a width greater than the width of the active layer ACT (e.g., greater than the width W2 of the second pattern ACT2) in the channel width direction of the transistor T1. Accordingly, a source region SR and a drain region DR of the active layer ACT can be separated in a stable manner.

In an embodiment, the gate insulating layer GI may have a length L2 greater than a length L1 of the gate electrode GE (or a channel length of the active layer ACT) in the channel length direction of the transistor T1 and may cover a portion of each of the source region SR and the drain region DR immediately adjacent to the channel region CH. Accordingly, an effective channel length of the transistor T1 can be secured in a stable manner.

As described above, according to embodiments, the first pattern ACT1 including the first oxide semiconductor having high mobility may be located in the central portion of the active layer ACT, and the second pattern ACT2 including the second oxide semiconductor having low mobility may be located in the edge portion of the active layer ACT such that the second pattern ACT2 surrounds the first pattern ACT1. In this arrangement, it is possible to suppress or reduce the formation of a parasitic conduction path in the edge portion of the active layer ACT due to hydrogen introduced from the periphery of the active layer ACT that could otherwise result without the inclusion of the relatively low-mobility second oxide semiconductor in the second pattern ACT2.

For example, when an entire area of the active layer ACT includes the high-mobility first oxide semiconductor, the conductivity of the edge portion of the active layer ACT may be increased by hydrogen diffused into the active layer ACT from the periphery of the active layer ACT (e.g., hydrogen diffused to the sides of the active layer ACT). Accordingly, leakage current may flow through the transistor T1, or the characteristics of the transistor T1 may change. For example, when the entire area of the active layer ACT includes the high-mobility first oxide semiconductor, unlike in the contemplated embodiments, an area where the second pattern ACT2 is formed in FIG. 5 may also include the high-mobility first oxide semiconductor. In this case, a parasitic conduction path may be formed as indicated by dotted arrows in FIG. 5, and carriers (e.g., electrons) may move along the parasitic conduction path. Accordingly, this may cause an abnormal phenomenon such as early turn-on of the transistor T1 or leakage current, thereby degrading the operating characteristics of the transistor T1 and lowering the reliability of a pixel PX and the display device 100 including the pixel PX.

On the other hand, when the edge portion of the active layer ACT includes the low-mobility second oxide semiconductor as in the contemplated embodiments, the introduction of hydrogen into the active layer ACT may be reduced or blocked, thereby suppressing a parasitic conduction path from being formed in the active layer ACT as indicated by the dotted arrows in FIG. 5. Accordingly, the abnormal operation of the transistor T1, such as early turn-on or leakage current, can be prevented, and the operating characteristics of the transistor T1 can be stabilized. Therefore, according to the contemplated embodiments, the mobility of the transistor T1 can be realized in a predictable way or improved by the presence of the first pattern ACT1, and the reliability of the transistor T1 can be improved by the presence of the second pattern ACT2. Accordingly, the operating characteristics and reliability of the transistor T1 and the display device 100 including the transistor T1 can be improved.

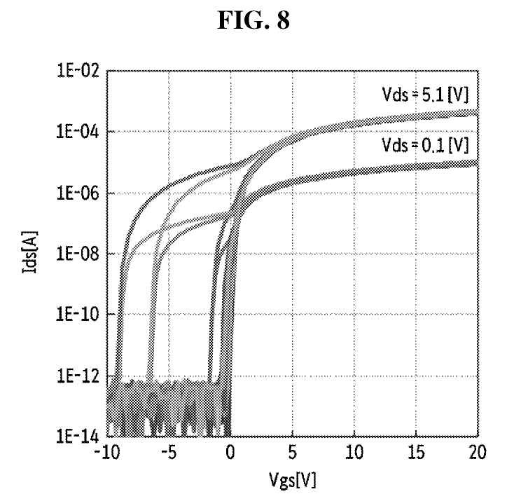

FIG. 8 is a graph illustrating the operating characteristics of a transistor including an active layer which includes only a high-mobility oxide semiconductor. For example, FIG. 8 is a graph illustrating a transfer curve of a transistor in which the entire active layer ACT includes a high-mobility oxide semiconductor, unlike in the contemplated embodiments.

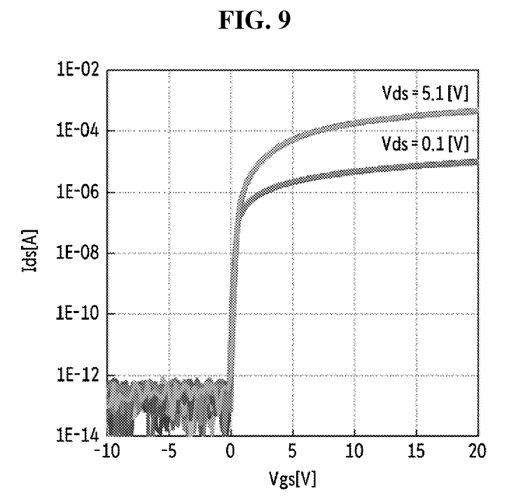

FIG. 9 is a graph illustrating the operating characteristics of a transistor including a first pattern and a second pattern according to an embodiment. For example, FIG. 9 is a graph illustrating a transfer curve of the transistor T1 according to the embodiment of FIGS. 4-7.

In FIGS. 8 and 9, Vgs represents a gate-source voltage of each transistor, Vds represents a drain-source voltage of each transistor, and Ids represents a drain-source current of each transistor.

Referring to FIGS. 8 and 9, in the case of the transistor including the active layer which includes only the high-mobility oxide semiconductor (e.g., a first oxide semiconductor), a parasitic conduction path may be formed by hydrogen introduced or diffused into sides of the active layer including the high-mobility oxide semiconductor. Accordingly, the transfer curve characteristics of the transistor may deteriorate, thus increasing the possibility of occurrence of early turn-on defects in the form of humps, as shown in FIG. 8 (rise in drain source current below a gate source voltage of zero).

On the other hand, in the case of the transistor T1 according to the contemplated embodiments, since a second pattern ACT2 including a low-mobility oxide semiconductor (e.g., a second oxide semiconductor) is located in an edge portion including sides of an active layer ACT, the formation of a parasitic conduction path can be suppressed. Accordingly, as shown in FIG. 9, the occurrence of humps can be prevented, and the operating characteristics of the transistor T1 can be improved.

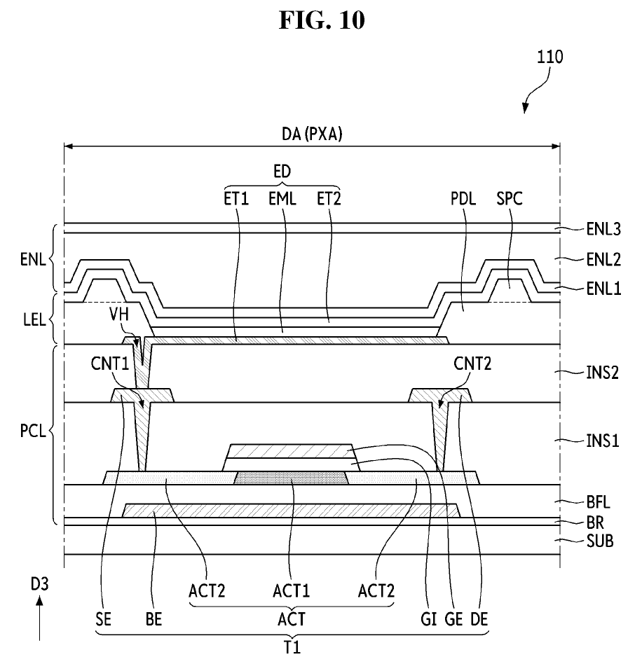

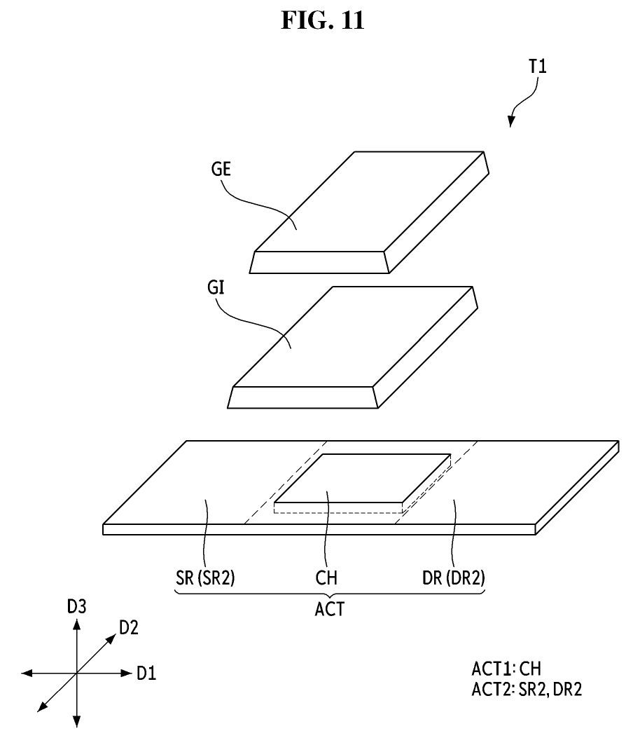

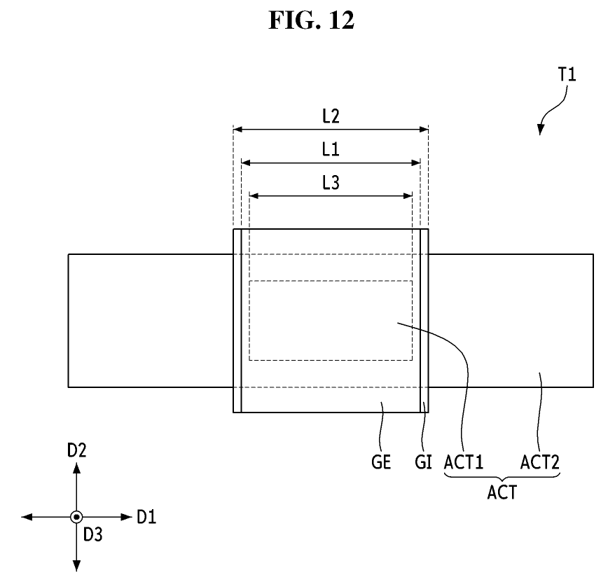

FIG. 10 is a cross-sectional view of a display panel according to an embodiment. FIG. 11 is an exploded perspective view illustrating an active layer ACT, a gate insulating layer GI, and a gate electrode GE of a transistor T1 according to an embodiment. FIG. 12 is a plan view illustrating the active layer ACT, the gate insulating layer GI, and the gate electrode GE of the transistor T1 according to the embodiment of FIG. 11. In one non-limiting example, FIGS. 11 and 12 show the active layer ACT, the gate insulating layer GI, and the gate electrode GE of the transistor T1 illustrated in FIG. 10.

FIGS. 10-12 show a different embodiment from FIGS. 4-7 in relation to the active layer ACT of the transistor T1. In the description of the embodiment of FIGS. 10-12, a redundant description of elements identical or similar to those of the above-described embodiment (FIGS. 4-7) will be omitted.

Referring to FIGS. 10-12, the active layer ACT may include a first pattern ACT1 including a first oxide semiconductor and a second pattern ACT2 including a second oxide semiconductor. The first pattern ACT1 may have a length L3 equal to or smaller than a length L1 of the gate electrode GE in the channel length direction of the transistor T1 and may be completely overlapped by the gate electrode GE in the thickness direction. For example, the first pattern ACT1 may be located entirely inside a region covered by the gate electrode GE, for example, in a channel region CH of the transistor T1. In this case, the gate insulating layer GI may cover (i.e., overlap) the entire first pattern ACT1 and a portion of the second pattern ACT2 (e.g., a portion of the second pattern ACT2 immediately adjacent to the first pattern ACT1) and may leave exposed another portion of the second pattern ACT2 (e.g., a second source region SR2 and a second drain region DR2).

In an embodiment, a portion of the second pattern ACT2 which overlaps the gate insulating layer GI in the thickness direction (e.g., a portion in contact with the first pattern ACT1) may be a portion of the channel region CH in which a channel is formed or may be a source region SR and/or a drain region DR in contact with the channel region CH.

In an embodiment, the length L3 of the first pattern ACT1 may be shorter than the length L1 of the gate electrode GE, and the first pattern ACT1 may be formed to a size corresponding to that of an area, in which an effective channel is formed, within the channel region CH of the transistor T1. For example, the first pattern ACT1 may have a length L3 substantially equal or similar to an effective channel length of the transistor T1. Accordingly, the characteristics (e.g., mobility) of the channel region CH of the transistor T1 may be maintained in substantially the same way or similarly to the embodiment of FIGS. 4-7, while the area occupied by the first pattern ACT1 in the active layer ACT is reduced. Therefore, the formation of a parasitic conduction path can be suppressed effectively.

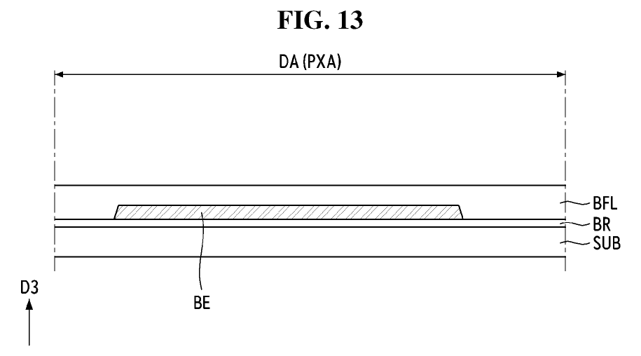

FIGS. 13-26 are cross-sectional views illustrating steps in a method of manufacturing a display device according to an embodiment. For example, FIGS. 13-26 are cross-sectional views illustrating steps in a method of manufacturing a display panel 110 included in a display device 100 according to an embodiment. FIGS. 13-26 show a sequence of manufacturing operations for forming a panel circuit layer PCL including a transistor T1 according to the embodiment of FIGS. 4-7 and a manufacturing operation for forming a light emitting element layer LEL on the panel circuit layer PCL.

As described above, the position or size (e.g., area) of a first pattern ACT1 may be changed in various ways according to embodiments of the present disclosure. For example, as in the embodiment of FIGS. 10-12, the first pattern ACT1 may have an area equal to or smaller than the area of a gate electrode GE and may be placed only in a region overlapping the gate electrode GE. The display panel 110 according to the embodiment of FIGS. 10-12 may be manufactured in a manner substantially identical or similar to the manufacturing method according to the embodiment of FIGS. 13-26, except for differences respecting the positions and/or sizes of the first pattern ACT1 and a second pattern ACT2.

Referring to FIG. 13 in addition to FIGS. 1-12, a substrate SUB including a display area DA may be prepared, and a barrier layer BR, a bottom electrode BE and a buffer layer BFL may be sequentially formed on the substrate SUB.

For example, the barrier layer BR may first be formed on the substrate SUB. The barrier layer BR may be formed by a process of forming an insulating film including an insulating material exemplified above. For example, the barrier layer BR may be formed by depositing an inorganic insulating material on the substrate SUB.

Next, the bottom electrode BE may be formed on the barrier layer BR. The bottom electrode BE may be formed by a process of forming a conductive film including a conductive material (e.g., at least one conductive material exemplified above) and a process of patterning the conductive film. In an embodiment, the process of patterning the conductive film may include a photolithography process. For example, the process of patterning the conductive film may include a photoresist process for forming a photoresist pattern needed to etch the conductive film into a shape corresponding to that of the bottom electrode BE, etc. and an etching process for forming the bottom electrode BE from the conductive film by etching the conductive film using the photoresist pattern as a mask. However, a patterning method for forming the bottom electrode BE is not limited to this method.

Next, the buffer layer BFL may be formed on the substrate SUB, the barrier layer BR, and the bottom electrode BE. The buffer layer BFL may be formed by a process of forming an insulating film including at least one insulating material (e.g., an inorganic insulating material) exemplified above.

If the display panel 110 does not include at least one of the barrier layer BR, the bottom electrode BE and the buffer layer BFL, the operation of forming at least one of the barrier layer BR, the bottom electrode BE or the buffer layer BFL may be omitted.

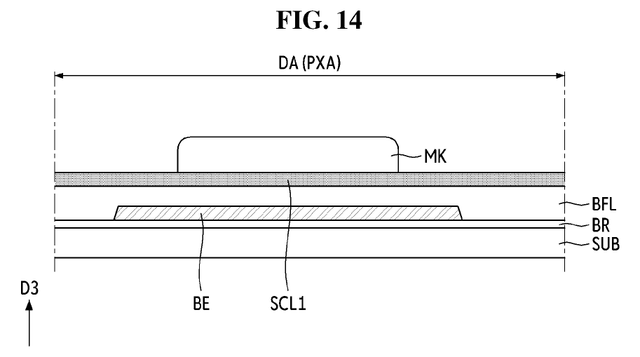

Referring to FIGS. 14-16, a first pattern ACT1 may be formed on the buffer layer BFL. The first pattern ACT1 may include a first oxide semiconductor.

For example, first, as illustrated in FIG. 14, a first semiconductor layer SCL1 including the first oxide semiconductor may be formed on the buffer layer BFL. The first semiconductor layer SCL1 may be formed by a process of forming the first semiconductor layer SCL1 including a high-mobility oxide semiconductor (e.g., indium-tin-gallium-zinc oxide (ITGZO), crystalline indium-gallium oxide (p-IGO), or other high-mobility oxide semiconductors) exemplified above as the first oxide semiconductor. For example, the first semiconductor layer SCL1 may be formed by depositing an entirety of the first oxide semiconductor on the buffer layer BFL.

After the formation of the first semiconductor layer SCL1, a mask MK covering a portion of the first semiconductor layer SCL1 may be placed at a position corresponding to a position where the first pattern ACT1 is to be formed. In an embodiment, the mask MK may be formed as a photoresist pattern including a photoresist material.

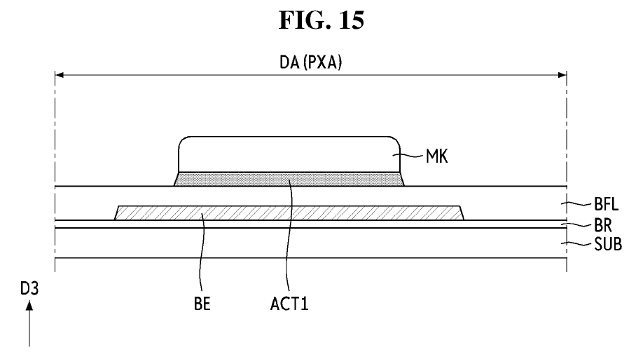

Next, as illustrated in FIG. 15, the first pattern ACT1 may be formed under the mask MK by etching the first semiconductor layer SCL1 using the mask MK.

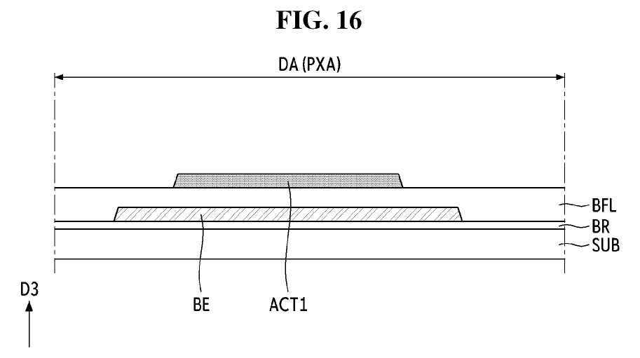

Next, as illustrated in FIG. 16, the mask MK may be removed. Accordingly, an upper surface of the first pattern ACT1 may be exposed.

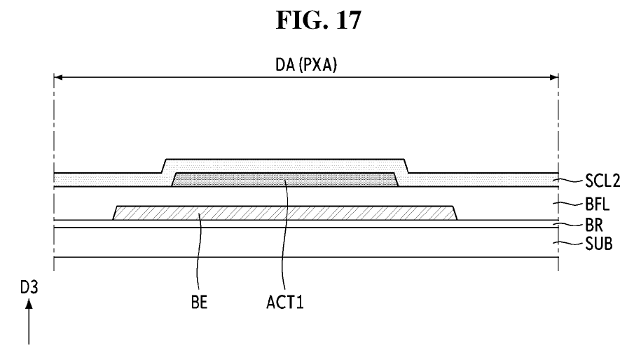

Referring to FIGS. 17-20, a second pattern ACT2 may be formed on the buffer layer BFL. The second pattern ACT2 may be formed using a second oxide semiconductor.

For example, first, as illustrated in FIG. 17, a second semiconductor layer SCL2 including the second oxide semiconductor may be formed on the buffer layer BFL and the first pattern ACT1. The second semiconductor layer SCL2 may be formed by a process of forming the second semiconductor layer SCL2 including the second oxide semiconductor (e.g., indium-gallium-zinc oxide (IGZO) or other low-mobility oxide semiconductors) which has mobility that is low relative to the mobility of the first oxide semiconductor. For example, the second semiconductor layer SCL2 may be formed by depositing an entirety of the second oxide semiconductor on the buffer layer BFL and the first pattern ACT1. The second semiconductor layer SCL2 may entirely cover the first pattern ACT1.

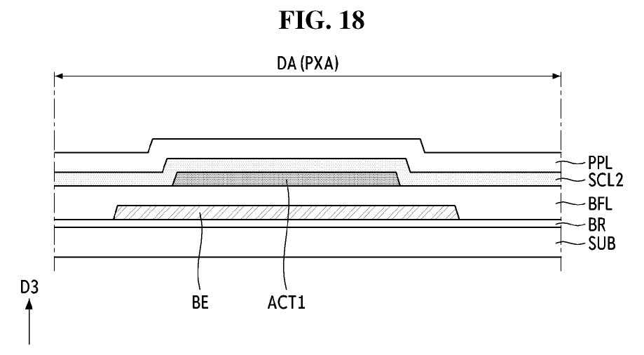

Next, as illustrated in FIG. 18, a protective layer PPL may be formed on the second semiconductor layer SCL2. The protective layer PPL may be a sacrificial layer that prevents damage to a film under the protective layer PPL, such as the first pattern ACT1, and helps planarize the surface in a subsequent process for removing the second semiconductor layer SCL2 on the first pattern ACT1 (e.g., a planarization polishing process for exposing the upper surface of the first pattern ACT1). For example, when a chemical mechanical planarization (CMP) or chemical mechanical polishing process is to be performed as the planarization polishing process for exposing the upper surface of the first pattern ACT1, the protective layer PPL may be formed using a material suitable for preventing excessive polishing of a film under the protective layer PPL and may act as a CMP buffer layer. For example, the protective layer PPL may be formed as an oxide layer including silicon oxide or other oxides.

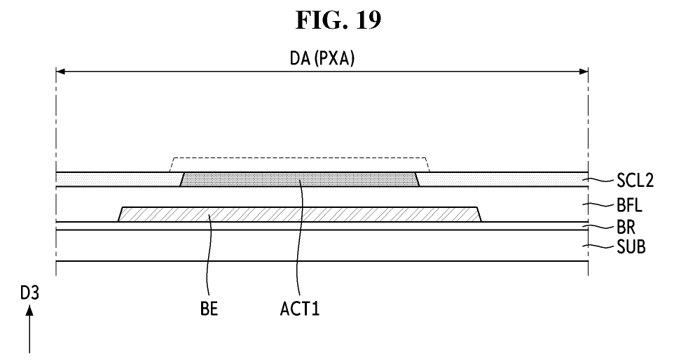

Next, as illustrated in FIG. 19, a planarization polishing process may be performed until a surface of the first pattern ACT1 is exposed. For example, the protective layer PPL and the second semiconductor layer SCL2 may be polished by a CMP process until the upper surface of the first pattern ACT1 is exposed. Accordingly, a portion of the second semiconductor layer SCL2, which overlaps the first pattern ACT1, and the protective layer PPL may be removed, and the upper surface of the first pattern ACT1 may be exposed. In addition, the surfaces of the first pattern ACT1 and the second semiconductor layer SCL2 may be planarized. The protective layer PPL may be removed by the planarization polishing process.

In an embodiment, the first pattern ACT1 and the second semiconductor layer SCL2 may be formed to have substantially the same or similar thicknesses (i.e., in the thickness direction, e.g., third direction D3). However, due to a difference in the material properties of the first pattern ACT1 and the second semiconductor layer SCL2, the thicknesses of the first pattern ACT1 and the second semiconductor layer SCL2 may also have some differences (e.g., over parts of one pattern compared to parts of the other pattern) as a result of the planarization process. The first pattern ACT1 and the second semiconductor layer SCL2 may be located substantially in the same plane (or at the same height within the transistor T1, i.e., the same height in the thickness direction), and the surfaces of the first pattern ACT1 and the second semiconductor layer SCL2 may be generally or substantially flat. In FIG. 19, the first pattern ACT1 and the second semiconductor layer SCL2 are in the same plane where the plane is coincident with the first direction D1 and the second direction D2.

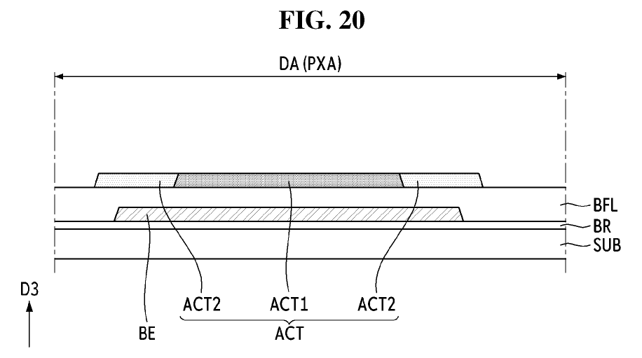

Next, the second semiconductor layer SCL2 may be etched by performing a process of patterning the second semiconductor layer SCL2. Accordingly, the second pattern ACT2 may be formed from the second semiconductor layer SCL2 as illustrated in FIG. 20. The second pattern ACT2 may be formed to surround the first pattern ACT1. For example, the second pattern ACT2 may be formed around the first pattern ACT1 to surround side surfaces of the first pattern ACT1 and may have an opening in a central portion to expose the upper surface of the first pattern ACT1, i.e., the second pattern ACT2 is formed so that none of the second pattern ACT2 covers the upper surface of the first pattern ACT1. In an embodiment, the second semiconductor layer SCL2 may be patterned into the second pattern ACT2 by a photolithography process. However, a patterning method for forming the second pattern ACT2 is not limited to this method.

An active layer ACT may be formed by the process described above with reference to FIGS. 14-20. The active layer ACT may be formed as an island-shaped pattern including the first pattern ACT1 located in a central portion and the second pattern ACT2 located in an edge portion that surrounds the side surfaces of the first pattern ACT1, as shown in FIG. 5, for example.

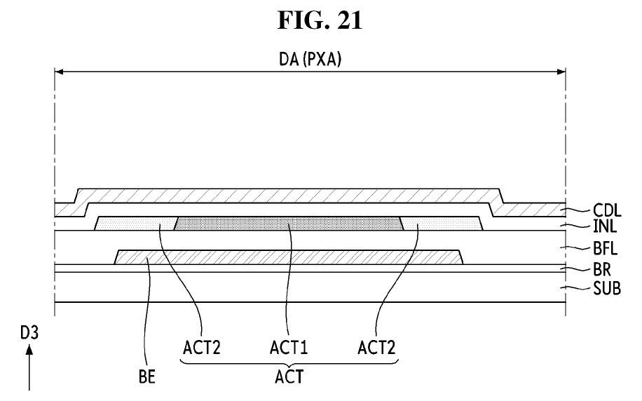

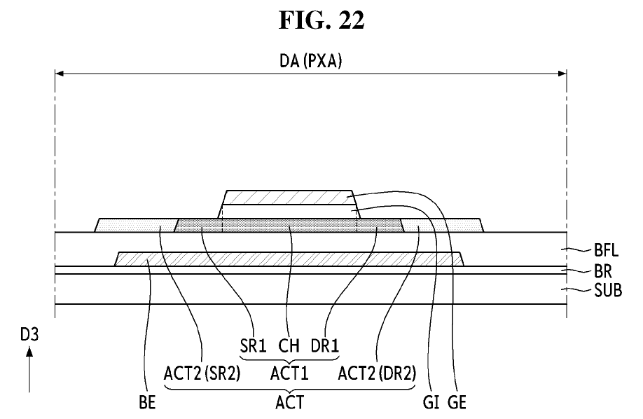

Referring to FIGS. 21 and 22, a gate insulating layer GI and a gate electrode GE may be formed on the active layer ACT. The gate insulating layer GI and the gate electrode GE may be formed on a portion of the active layer ACT including at least a portion (e.g., a channel region CH) of the first pattern ACT1.

For example, first, as illustrated in FIG. 21, an insulating layer INL and a conductive layer CDL may be sequentially formed on the buffer layer BFL and the active layer ACT. For example, the insulating layer INL may be formed to cover the entire active layer ACT by depositing an entirety of an insulating material (e.g., at least one inorganic insulating material exemplified as the material of the gate insulating layer GI) on the buffer layer BFL and the active layer ACT. Then, the conductive layer CDL may be formed to cover the insulating layer INL by depositing an entirety of a conductive material (e.g., at least one conductive material exemplified as the material of the gate electrode GE) on the insulating layer INL.

Next, as illustrated in FIG. 22, the gate insulating layer GI and the gate electrode GE may be formed by etching the insulating layer INL and the conductive layer CDL. In an embodiment, after the gate electrode GE is formed from the conductive layer CDL by a photolithography process, the gate insulating layer GI may be formed by etching the insulating layer INL into a shape and/or size corresponding to a shape and/or size of the gate electrode GE.

In an embodiment, the insulating layer INL and the conductive layer CDL may be patterned substantially simultaneously or sequentially by etching the insulating layer INL and the conductive layer CDL substantially simultaneously or sequentially using one mask formed in one photoresist process. Accordingly, the gate insulating layer GI and the gate electrode GE of the transistor T1 may be formed in shapes and sizes corresponding to each other.

In an embodiment, the insulating layer INL and the conductive layer CDL may be sequentially etched using respective masks formed in respective photoresist processes. In this case, the gate insulating layer GI may be formed by etching the insulating layer INL fist, and then the gate electrode GE may be formed by etching the conductive layer CDL. Alternatively, in an opposite order, the gate electrode GE may be formed first, and then the gate insulating layer GI may be formed. In addition, when the insulating layer INL and the conductive layer CDL are etched using respective masks, sizes and/or shapes of the insulating layer INL and the conductive layer CDL can be independently controlled.

In the process of forming the gate insulating layer GI by etching the insulating layer INL, the properties of the active layer ACT may be changed such that the active layer ACT has different characteristics in different portions. Accordingly, the active layer ACT may be divided into a plurality of regions having different characteristics.

For example, in a portion not covered with the gate insulating layer GI and the gate electrode GE, oxygen vacancies may be generated in an oxide semiconductor, which forms the active layer ACT, due to an etching gas, etc. Accordingly, the active layer ACT may be divided into a plurality of regions (e.g., the channel region CH, a source region SR and a drain region DR) having different characteristics. In an embodiment, oxygen vacancies may be generated primarily in a portion of the active layer ACT which does not overlap the gate insulating layer GI and the gate electrode GE (e.g., the source region SR and the drain region DR).

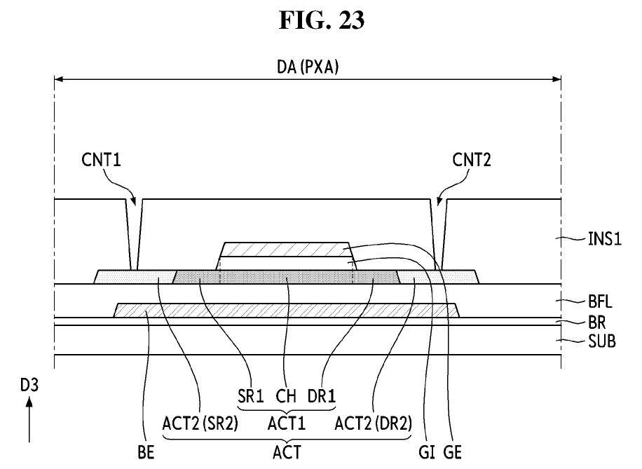

Referring to FIG. 23, a first insulating layer INS1 may be formed on the buffer layer BFL to cover the active layer ACT, the gate insulating layer GI, and the gate electrode GE. The first insulating layer INS1 may be formed by a process of forming an insulating film which includes at least one insulating material (e.g., an inorganic insulating material) exemplified above.

Hydrogen may be introduced into the active layer ACT during the process of forming the first insulating layer INS1 and/or a heat treatment process performed before and after the process of forming the first insulating layer INS1. For example, hydrogen may be introduced into the source region SR and the drain region DR of the active layer ACT, thereby increasing carrier concentration. Accordingly, the conductivity of the source region SR and drain region DR may be increased.

After the first insulating layer INS1 is formed, at least one contact hole may be formed to penetrate the first insulating layer INS1. For example, a first contact hole CNT1 and a second contact hole CNT2 exposing a portion of the source region SR and a portion of the drain region DR of the active layer ACT, respectively, may be formed by an etching process using a mask.

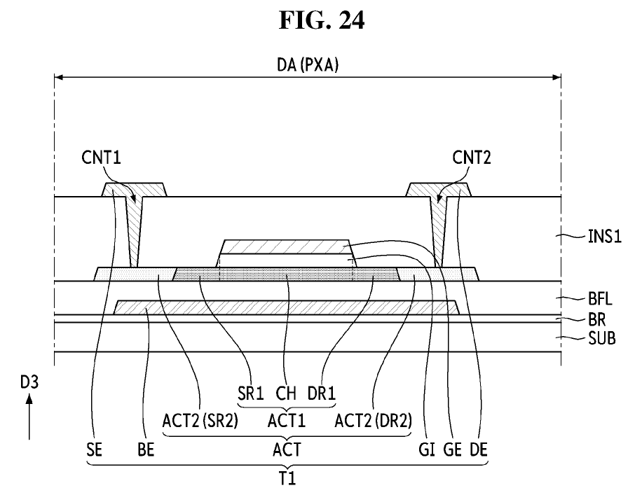

Referring to FIG. 24, a source electrode SE and a drain electrode DE (or at least one connection electrode electrically connected to the source region SR and/or the drain region DR) may be formed on the first insulating layer INS1. The source electrode SE and the drain electrode DE may be formed by a process of forming a conductive film including at least one conductive material exemplified above and a process of patterning the conductive film. Accordingly, the transistor T1 may be formed.

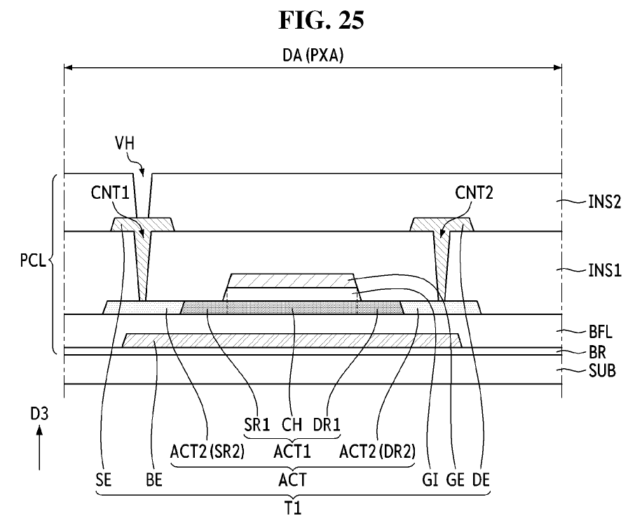

Referring to FIG. 25, a second insulating layer INS2 may be formed on the first insulating layer INS1 to cover the source electrode SE and the drain electrode DE (or at least one connection electrode). The second insulating layer INS2 may be formed by a process of forming an insulating film including at least one organic insulating material exemplified above.

After the second insulating layer INS2 is formed, a via hole VH may be formed in each pixel area PXA to penetrate the second insulating layer INS2. For example, the via hole VH may be formed to expose an electrode (e.g., the source electrode SE) of the transistor T1 located in each pixel area PXA.

A panel circuit layer PCL may be formed on the substrate SUB by the process described above with reference to FIGS. 13-25. The panel circuit layer PCL may include the transistor T1 including the active layer ACT according to embodiments.

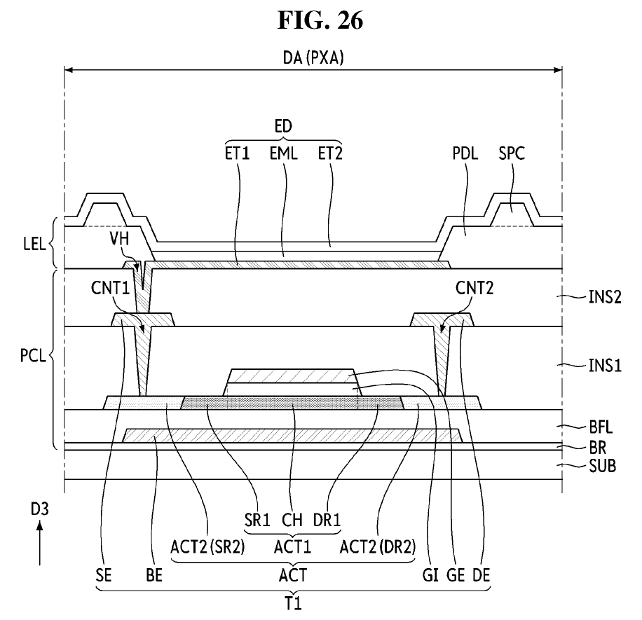

Referring to FIG. 26, a light emitting element layer LEL may be formed on the panel circuit layer PCL. For example, a first electrode ET1 of a light emitting element ED may be formed on the second insulating layer INS2. The first electrode ET1 of the light emitting element ED may be electrically connected to the transistor T1 through the via hole VH. Next, a pixel defining layer PDL, a spacer SPC, a light emitting layer EML of the light emitting element ED, and a second electrode ET2 of the light emitting element ED may be sequentially formed on the second insulating layer INS2 and the first electrode ET1 of the light emitting element ED. Accordingly, the light emitting element layer LEL including the light emitting element ED may be formed.

Through the above-described process, the panel circuit layer PCL and the light emitting element layer LEL of the display panel 110 according to the embodiment may be formed. When the display panel 110 includes an encapsulation layer ENL as in the embodiments of FIGS. 4 and 10, the encapsulation layer ENL may be formed on the light emitting element layer LEL. For example, a first encapsulation layer ENL1, a second encapsulation layer ENL2, and a third encapsulation layer ENL3 may be sequentially formed on the second electrode ET2 of the light emitting element ED (or an inorganic capping layer covering the light emitting element ED). Accordingly, a display panel 110 and/or a display device 100 including the display panel 110 may be manufactured by utilizing the above-described process in the overall manufacturing process.

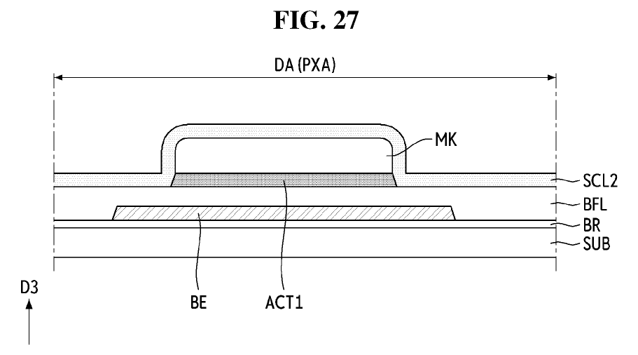

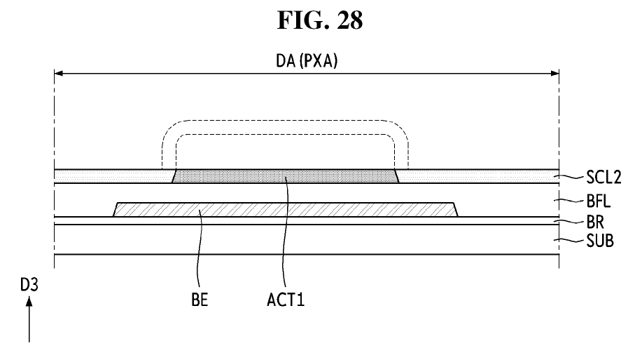

FIGS. 27 and 28 are cross-sectional views illustrating a method of manufacturing a display device according to an embodiment. FIGS. 27 and 28 show a different embodiment from FIGS. 13-26 in that in FIGS. 27 and 28, a different process is used in a method of exposing an upper surface of a first pattern ACT1 by removing a second semiconductor layer SCL2 on the first pattern ACT1.

Referring to FIG. 27, after the first pattern ACT1 is formed, the second semiconductor layer SCL2 may be formed while a mask MK covering the first pattern ACT1 remains. For example, a first semiconductor layer SCL1 may be formed on a buffer layer BFL by the process described above with reference to FIGS. 14 and 15, and the first pattern ACT1 may be formed by etching the first semiconductor layer SCL1. Then, while the mask MK (e.g., a photoresist pattern used as an etching mask) remains on the first pattern ACT1, the second semiconductor layer SCL2 may be formed by depositing a second oxide semiconductor on the buffer layer BFL, the first pattern ACT1, and the mask MK. The second semiconductor layer SCL2 may entirely cover the buffer layer BFL, the first pattern ACT1, and the mask MK. In an embodiment, the second semiconductor layer SCL2 may be formed by atomic layer deposition (ALD) to secure step coverage.

Referring to FIG. 28, the mask MK and the second semiconductor layer SCL2 may be removed from the first pattern ACT1 using a lift-off method. For example, a portion of the second semiconductor layer SCL2 which is located on the mask MK and the mask MK itself may be removed by a photoresist strip process to expose the upper surface of the first pattern ACT1.

Next, as illustrated in FIG. 20, the second semiconductor layer SCL2 may be etched to form an active layer ACT including the first pattern ACT1 and a second pattern ACT2. Since a process after the formation of the active layer ACT may be performed in the same manner as in the previously described embodiment, a redundant description thereof will be omitted.

The display device 100 according to at least one of the embodiments described above can be applied and incorporated into various electronic devices. An electronic device according to an embodiment includes the above-described display device 100 (or a display module including a display panel 110 according to at least one embodiment) and may further include modules or devices having other additional functions in addition to the functions of the display device 100.

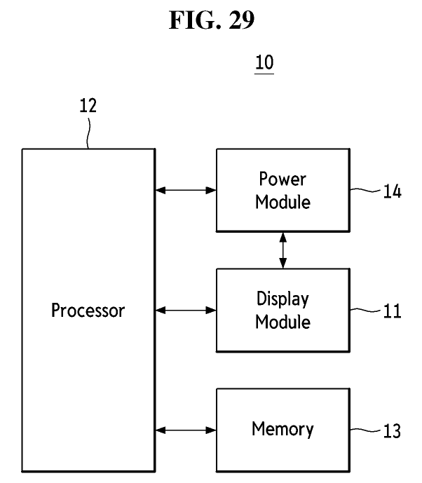

FIG. 29 is a block diagram of an electronic device 10 according to an embodiment.

Referring to FIG. 29, the electronic device 10 according to the embodiment may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include a display panel 110 for displaying an image. For example, the display module 11 may include a display panel 110 according to at least one of the embodiments described above.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. For example, the memory 13 may store an image data signal and/or an input control signal.

The processor 12 may control the display module 11 using information stored in the memory 13. The processor 12 is configured to transmit, and may transmit an image data signal and/or an input control signal stored in the memory 13 to the display module 11. For example, when the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module, which generates power necessary for the operation of the electronic device 10 by converting power supplied by the power supply module.

At least one of the elements of the electronic device 10 described above may be included in the display device 100 according to the above-described embodiments. In addition, some of individual modules functionally included in one module may be included in the display device 100, and other modules may be provided separately from the display device 100. For example, the display device 100 may include the display module 11, and the processor 12, the memory 13 and the power module 14 may be provided in other devices within the electronic device 10 other than the display device 100.

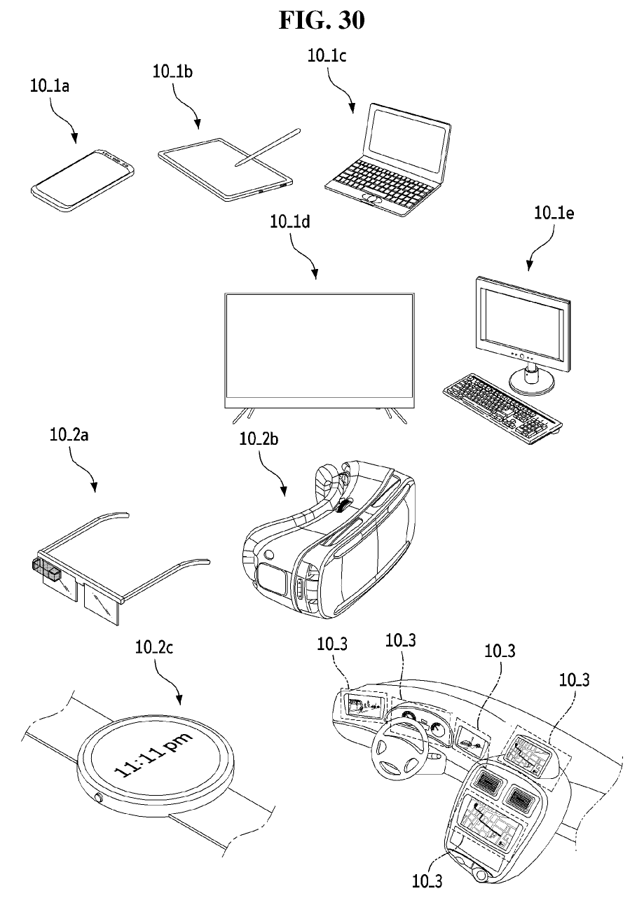

FIG. 30 is a schematic diagram of electronic devices according to various embodiments.

Referring to FIG. 30, various electronic devices to which a display device 100 according to any of the contemplated embodiments may be applied and incorporated into may include not only image display electronic devices, such as a smartphone 10_1a, a tablet PC 10_1b, a laptop 10_1c, a television 10_1d and a desk monitor 10_1e, but also wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument panel, a center fascia and a dashboard of a vehicle.

As described above, embodiments provide a transistor T1, and a display device 100 and/or an electronic device 10 including the transistor T1. Here, the transistor T1 includes a first pattern ACT1 which includes a first oxide semiconductor having high mobility and a second pattern ACT2 which surrounds side surfaces of the first pattern ACT1 and includes a second oxide semiconductor having lower mobility than the first oxide semiconductor. In addition, the embodiments provide a method of manufacturing the display device 100, which includes a method of manufacturing the transistor T1 including the first pattern ACT1 and the second pattern ACT2.

According to embodiments, a display device 100 that includes a transistor T1 and a display device 100 applied to an electronic device 10 that includes a transistor T1 both have high mobility and stable operating characteristics. Further, embodiments also include a method of manufacturing the display device 100, either independently or as part of an electronic device 10. In an example, the transistor T1 may have high-mobility characteristics due to a first pattern ACT1 and may have stable operating characteristics because leakage current and early turn-on are suppressed by a second pattern ACT2 surrounding the first pattern ACT1. Accordingly, the operating characteristics and reliability of the transistor T1, and the display device 100 and/or the electronic device 10 which include the transistor T1, can be improved.

In concluding the detailed description, persons skilled in the art will appreciate that many variations and modifications can be made to the embodiments without substantially departing from the principles of the present disclosure. Therefore, the disclosed embodiments of the present disclosure are used in a generic and descriptive sense only and not for purposes of limitation.

What is claimed is:

1. A display device comprising:
a substrate; and
a transistor comprising an active layer located on the substrate, and a gate insulating layer and a gate electrode located on a portion of the active layer,
wherein the active layer comprises:
a first pattern located in a central portion of the active layer such that the first pattern overlaps the gate electrode in a thickness direction of the active layer, the first pattern comprising a first oxide semiconductor; and
a second pattern located in an edge portion of the active layer that surrounds the first pattern, the second pattern comprising a second oxide semiconductor having lower mobility than the first oxide semiconductor.

2. The display device of claim 1, wherein
the second pattern covers only side surfaces among surfaces of the first pattern and leaves exposed an upper surface of the first pattern, and
at least a portion of the upper surface of the first pattern is covered by the gate insulating layer.

3. The display device of claim 1, wherein the first pattern and the second pattern do not overlap in the thickness direction of the active layer.

4. The display device of claim 3, wherein the first pattern and the second pattern are located in a first plane perpendicular to the thickness direction of the active layer.

5. The display device of claim 1, wherein
the first pattern has a first length measured in a channel length direction of the transistor and the gate electrode has a second length measured in the channel length direction, the first length being longer than the second length such that the first pattern protrudes beyond opposite sides of the gate electrode in the channel length direction, and
the gate insulating layer covers only a first portion of the first pattern that overlaps the gate electrode in the thickness direction and a second portion of the first pattern separate from the first portion is not covered by the gate insulating layer.

6. The display device of claim 1, wherein
the first pattern has a first length measured in a channel length direction of the transistor and the gate electrode has a second length measured in the channel length direction, the first length being shorter than the second length such that the first pattern completely overlaps the gate electrode in the thickness direction, and
the gate insulating layer covers an entirety of the first pattern and a portion of the second pattern that is less than an entirety of the second pattern.

7. The display device of claim 1, wherein each of the first pattern and the second pattern comprises a metal oxide comprising at least one of indium, gallium, zinc, tin, hafnium, zirconium, or aluminum.

8. The display device of claim 1, wherein
the first pattern comprises indium-tin-gallium-zinc oxide or crystalline indium-gallium oxide, and
the second pattern comprises indium-gallium-zinc oxide.

9. The display device of claim 1, further comprising:
a first insulating layer covering the active layer, the gate insulating layer and the gate electrode; and
at least one of a source electrode or a drain electrode located on the first insulating layer and electrically connected to the active layer.

10. The display device of claim 9, further comprising:
a second insulating layer located on the first insulating layer; and
a light emitting element located on the second insulating layer and electrically connected to the source electrode or the drain electrode.

11. An electronic device comprising:
a display module comprising a display panel; and
a processor configured to transmit an image data signal to the display module,
the display panel comprising:
a substrate; and
a transistor comprising an active layer located on the substrate, and a gate insulating layer and a gate electrode located on a portion of the active layer,
wherein the active layer comprises:
a first pattern located in a central portion of the active layer such that the first pattern overlaps the gate electrode in a thickness direction of the active layer, the first pattern comprising a first oxide semiconductor; and
a second pattern located in an edge portion of the active layer that surrounds the first pattern, the second pattern comprising a second oxide semiconductor having lower mobility than the first oxide semiconductor.

12. The electronic device of claim 11, wherein
the second pattern covers only side surfaces among surfaces of the first pattern and leaves exposed an upper surface of the first pattern, and
at least a portion of the upper surface of the first pattern is covered by the gate insulating layer.

13. The electronic device of claim 11, wherein the first pattern and the second pattern do not overlap in the thickness direction of the active layer.

14. The electronic device of claim 11, wherein
the first pattern has a first length measured in a channel length direction of the transistor and the gate electrode has a second length measured in the channel length direction, the first length being longer than the second length such that the first pattern protrudes beyond opposite sides of the gate electrode in the channel length direction, and
the gate insulating layer covers only a first portion of the first pattern that overlaps the gate electrode in the thickness direction and a second portion of the first pattern separate from the first portion is not covered by the gate insulating layer.

15. The electronic device of claim 11, wherein
the first pattern has a first length measured in a channel length direction of the transistor and the gate electrode has a second length measured in the channel length direction, the first length being shorter than the second length such that the first pattern completely overlaps the gate electrode in the thickness direction, and
the gate insulating layer covers an entirety of the first pattern and a portion of the second pattern that is less than an entirety of the second pattern.

16. A method of manufacturing a display device, the method comprising:
forming an active layer on a substrate such that the active layer comprises a first pattern comprising a first oxide semiconductor and a second pattern comprising a second oxide semiconductor having lower mobility than the first oxide semiconductor; and
forming a gate insulating layer and a gate electrode on a portion of the active layer that includes at least a portion of the first pattern,
wherein the first pattern is located in a central portion of the active layer, and the second pattern is located in an edge portion of the active layer such that the second pattern surrounds the first pattern.

17. The method of claim 16, wherein the forming of the active layer comprises:
forming the first pattern on the substrate;
forming a second semiconductor layer on the substrate, the second semiconductor layer comprising the second oxide semiconductor and covering an entirety of the first pattern;
forming a protective layer on the second semiconductor layer;
removing both a first portion of the second semiconductor layer that overlaps the first pattern in a thickness direction of the display device, and the protective layer by performing a planarization polishing process until an upper surface of the first pattern is exposed; and
forming the second pattern by etching a second portion of the second semiconductor layer remaining after removing the first portion of the second semiconductor layer.

18. The method of claim 16, wherein the forming of the active layer comprises:
forming a first semiconductor layer on the substrate, the first semiconductor layer comprising the first oxide semiconductor;
placing a mask on the substrate such that the mask covers a portion of the first semiconductor layer, and forming the first pattern by etching the first semiconductor layer;
forming a second semiconductor layer on the substrate, the second semiconductor layer comprising the second oxide semiconductor and covering an entirety of the first pattern and the mask;
exposing an upper surface of the first pattern by removing a first portion of the second semiconductor layer located on the mask, and by removing the mask; and
forming the second pattern by etching a second portion of the second semiconductor layer remaining after removing the first portion of the second semiconductor layer.

19. The method of claim 16, further comprising:
forming a first insulating layer on the substrate such that the first insulating layer covers the active layer, the gate insulating layer and the gate electrode; and
forming at least one of a source electrode or a drain electrode, the at least one of the source electrode or the drain electrode being electrically connected to the active layer through a contact hole penetrating the first insulating layer, and the at least one of the source electrode or the drain electrode being disposed on the first insulating layer.

20. The method of claim 19, further comprising:
forming a second insulating layer on the first insulating layer, the second insulating layer covering the at least one of the source electrode or the drain electrode; and
forming a light emitting element on the second insulating layer, the light emitting element being electrically connected to the source electrode or the drain electrode through a via hole penetrating the second insulating layer.
